(19) United States
(12) Patent Application Publication
(10) Pub. No.: US 2011/0278678 A1
(43) Pub. Date: Nov. 17, 2011

(54) SEMICONDUCTOR DEVICE AND METHOD FOR MANUFACTURING SAME

(75) Inventors: Yasumori Fukushima, Osaka (JP); Yutaka Takafuji, Osaka (JP)

(73) Assignee: SHARP KABUSHIKI KAISHA, Osaka (JP)

(21) Appl. No.: 13/146,176

(22) PCT Filed: Dec. 17, 2009
(86) PCT No.: PCT/JP2009/071049

§ 371 Date: Jul. 25, 2011

(30) Foreign Application Priority Data
Jan. 29, 2009 (JP) 2009-018674

(51) Int. Cl. H01L 27/092; H01L 21/28; H01L 29/772

(52) U.S. Cl. 257/369; 257/288; 438/597; 257/E27.062; 257/E29.242; 257/E21.158

(57) ABSTRACT

This invention provides a semiconductor device having a semiconductor element that has low-resistance and a stable contact connection, even when the wiring is connected from the side of the single-crystal silicon layer on which the impurity concentration is lower. This invention provides a semiconductor device comprising, on a substrate, a semiconductor device having a single-crystal semiconductor film and a wiring connected to the single-crystal semiconductor film, and in the single-crystal semiconductor film, an impurity concentration on one surface side is different from an impurity concentration on another surface side, the wiring being connected to the surface side on which the impurity concentration is lower, the resistivity of a region of the single-crystal semiconductor film to which the wiring is connected being no less than 1 μΩcm and no more than 0.01 Ωcm.

### TECHNICAL FIELD

The present invention relates to a semiconductor device and the method for manufacturing same. More specifically, it relates to a semiconductor device that is well-suited to a display device such as a liquid crystal display device, an organic electroluminescent display device, or the like, and to the manufacturing method thereof.

### BACKGROUND ART

Semiconductor devices are electronic devices provided with active elements that take advantage of the electrical characteristics of semiconductors, and are used broadly in, for example, audio equipment, communications equipment, computers, electronics, and the like. Of these, semiconductor devices that are provided with three-terminal active elements such as metal-oxide-semiconductor (MOS)-type thin-film transistors are used as switching elements that are provided for each individual pixel in display devices such as active-matrix-type liquid crystal display devices (hereinafter termed “liquid crystal displays”) and organic electroluminescent display devices (hereinafter termed “organic EL displays”), and in the control circuitry for controlling individual pixels.

A silicon-on-insulator (SOI) substrate, which is a silicon substrate wherein a single-crystal silicon (Si) layer is formed on the surface of an insulating layer, is well-known as a semiconductor portion for forming a semiconductor device. The SOI substrate enables a reduction in the parasitic capacitance and an increase in the insulation resistance through the formation of the device, such as a transistor, thereon. That is, it enables an improvement in device performance and integration.

In order to increase device operating speed and further decrease parasitic capacitance, preferably the thickness of the single-crystal silicon film on the SOI substrate should be made thin. Methods for forming the SOI substrate include chemical mechanical polishing (CMP), methods that use porous silicon, and the like. In addition, in a method for forming a single-crystal silicon layer through performing hydrogen implantation, a “smart cut” method, in which hydrogen is implanted into a semiconductor substrate and, after bonding to another substrate, the semiconductor substrate is separated along the hydrogen implantation layer through a heat treatment, so as to be transferred onto the other substrate, has been proposed by Bruel. (See, for example, Non-patent Documents 1 and 2.). This technique enables the formation of a silicon-on-insulator (SOI) substrate that is a silicon substrate whereon a single-crystal silicon film is formed on the surface of an insulating layer. The formation of devices, such as transistors, in such a substrate structure enables a decrease in parasitic capacitance and enables an increase in insulation resistance, thus enabling improved device performance and integration.

Additionally, technologies for bonding together hydrophilic planarized oxide films have been developed in relation to technologies for transferring a semiconductor substrate to another substrate. Moreover, in regards to technologies for transferring a portion of a semiconductor substrate to a substrate for a display device, a large substrate for an active-matrix-type display devices in which single-crystal silicon substrates are laid out in tiles over the entirety of the glass substrate, or formed on portions of the glass substrate, has been developed. In addition, there have been papers published regarding “thermal donors” that are produced within the silicon. (See, for example, Non-patent Document 3.). Moreover, the connection from the gate insulating film side of a single-crystal semiconductor film to the source region, and wiring through a metal silicide, in a technology for transferring a semiconductor element to another substrate, have also been disclosed. (See, for example, Patent Document 1.)

### RELATED ART DOCUMENTS

### Patent Document

Patent Document 1: WO 2008/084628

### Non-Patent Documents

Non-Patent Document 1: Michel Bruel, “Silicon on insulator material technology,” Electronics Letters, USA, 1995, Volume 31, No. 14, pages 1201-1202
Non-Patent Document 2: Michel Bruel (and 3 others), “Smart-Cut: A New Silicon On Insulator Material Technology Based on Hydrogen Implantation and Wafer Bonding,” Japanese Journal of Applied Physics, Japan, 1997, Volume 36, No. 3B, pages 1636-1641
Non-Patent Document 3: H. J. Stein and S. K. Hahn, “Hydrogen introduction and hydrogen-enhanced thermal donor formation in silicon,” Journal of Applied Physics, USA, 1994, Volume 75, No. 7, pages 3477-3484

### SUMMARY OF THE INVENTION

### Problems to be Solved by the Invention

In such a situation, the present inventors have discovered that, in relation to semiconductor devices that have semiconductor elements such as metal-oxide-semiconductor (MOS) transistors, or the like, it is possible to form semiconductor elements using a single-crystal semiconductor film on an insulating substrate, such as a glass substrate, by separating a portion of a single-crystal semiconductor substrate through the formation of a hydrogen implantation layer. However, because conventionally a method has been used wherein only a single transfer is performed, it has not been possible to fully restore the characteristics of the transistors, given the thermal donor effect of the hydrogen ions and the deactivation of the boron (B) that is the acceptor, due to the inability to perform a high temperature heat treatment given the thermal durability of the substrate, such as a glass substrate, that is the substrate on the side to which the semiconductor elements are transferred. This is a phenomenon that is unique to cases wherein the heat treatments need to be performed at medium and low temperatures, rather than in the case of the LSI technology wherein heat treatments can be performed at high temperatures.

Given this, investigations were made into methods by which to use high temperatures for the temperatures at which the heat treatments are performed, through transferring to an intermediate substrate with greater thermal durability than that of the insulating substrate, such as a glass substrate, which has inferior thermal durability. However, it became apparent that there are the following problems with fabricating a semiconductor element using an intermediate substrate. When fabricating a MOS transistor, or the like, the peeling layer is formed by implanting a peeling substance into the silicon substrate after the formation of the impurity regions that are the source regions or drain regions. Following this, after first bonding to the intermediate substrate and performing a heat treatment, and cleaving at the peeling layer, source wirings and drain wirings are connected to the source and drain regions of the MOS transistors, and in this case, the wirings are connected to the single-crystal silicon layer from the side opposite from the gate electrode. Normally, for the source regions and the drain regions, impurity regions are formed through performing ion implantation from the gate insulating film side using the gate electrode, and the like, as a mask, thus making it possible to reduce the resistivity and to achieve a low-resistance contact connection (an electrical connection), given the presence of the high concentration of impurities near the surface of the single-crystal silicon film on the gate insulator film side.

However, in the method that uses the intermediate substrate, a contact hole is provided in the interlayer insulating film, which is provided on the side of the single-crystal semiconductor film that is opposite from the gate electrode, in order to connect the wiring and the source or the drain region; that is, the wiring is connected from the face on the side that is opposite from that of the gate electrode. It was found that this makes it difficult to obtain a low-resistance contact connection between the wiring and the source or drain region by merely having the wiring contact the surface of the single-crystal silicon film.

The present invention is the result of contemplation on the situation set forth above, and an object thereof is to provide a semiconductor device that is provided with a semiconductor element having low-resistance and stable contact connection, even when the wiring is connected from the side of the single-crystal silicon layer wherein the impurity concentration is low.

### Means for Solving the Problems

The present inventors engaged in earnest investigations focusing on semiconductor devices wherein wirings are connected from the side with the low impurity concentration to a single-crystal silicon film wherein the impurity concentration on one face thereof is lower than that of the other face. The present inventors discovered that when the wiring is merely connected from the side of the single-crystal semiconductor film wherein the impurity concentration is low, it is difficult to reduce the contact resistance between the wiring and the single-crystal semiconductor film, and further discovered that it is possible to obtain low-resistance and a stable contact connection by having the single-crystal semiconductor film be connected to the wiring from the side wherein the impurity concentration is low, and by making the resistivity of the single-crystal semiconductor layer in the region in which the wiring is connected be no less than 1 μΩcm and no more than 0.01 Ωcm, and realized that this superbly resolves the problems set forth above, thereby arriving at the present invention.

That is, the present invention is a semiconductor device having, on a substrate, a single-crystal semiconductor film and a semiconductor element that includes a wiring that is connected to the single-crystal semiconductor film, wherein, in the single-crystal semiconductor film, the impurity concentration on the face on one side is different from the impurity concentration on the face on the other side; a wiring is connected from the face on the side wherein the impurity concentration is low; and the resistivity in the region in which the wiring is connected is no less than 1 μΩcm and no more than 0.01 Ωcm (hereinafter termed the “first semiconductor device according to the present invention”).

The present invention will be described in detail below.

The first semiconductor device according to the present invention has, on a substrate, a single-crystal semiconductor film and a semiconductor element that includes a wiring that is connected to the single-crystal semiconductor film. There is no particular limitation on the substrate, and an insulating substrate, such as a glass substrate, a resin substrate, a plastic substrate, or the like, can be used appropriately. Note that when the term “substrate” is used alone in the present specification, it means a substrate on which a semiconductor device is structured according to the present invention.

The single-crystal semiconductor layer may be obtained by separating a portion of a single-crystal semiconductor substrate. For example, preferably the single-crystal semiconductor film is peeled at a peeling layer that includes a peeling substance, formed in a single-crystal semiconductor substrate. More specifically, the single-crystal semiconductor layer can be obtained by forming a peeling layer by implanting a peeling substance into a single-crystal semiconductor substrate, bonding to another substrate the single-crystal semiconductor substrate that has a semiconductor element or a portion of a semiconductor element formed thereon, and thereafter by peeling at the peeling layer. The use of the single-crystal semiconductor film enables operations that are faster and more stable than those in a non-single-crystal semiconductor layer, such as an amorphous silicon film or a polysilicon film formed through a vapor deposition technique, or the like, and enables higher levels of integration and semiconductor elements with higher levels of reliability.

Insofar as the semiconductor element is formed with wirings connected to the single-crystal semiconductor film, there are no particular limitations thereon; however, normally it is formed with two wirings connected to the single-crystal semiconductor film. The semiconductor element may, for example, be a diode that is a two-terminal element, or a transistor that is a three-terminal element. The types of semiconductor elements will be described in detail below.

In the single-crystal semiconductor film, the impurity concentration on the face on one side is different from the impurity concentration on the face on the other side. Such a single-crystal semiconductor film can be produced, for example, by the implantation of an impurity element from the face on the side that will have the higher impurity concentration. The impurity concentration can be measured using an element analyzing method in which secondary ion mass spectroscopy (SIMS) is used. Here, the “impurity concentration on the face on one side” can be found by measuring the impurity concentration in the vicinity of the surface of the single-crystal semiconductor film, for example, in the portion from the surface to a depth of 5 nm. The “impurity concentration on the face on the other side” can be measured similarly.

The aforementioned single-crystal semiconductor film preferably has an impurity concentration gradient wherein the impurity concentration increases from the face on the one side that has the low impurity concentration towards the face on the other side, wherein the impurity concentration is high. That is, the single-crystal semiconductor film preferably has an impurity region in which the impurity concentration becomes higher from the face on the one side wherein the impurity concentration is low towards the face on the other side wherein the impurity concentration is high. Preferably, this impurity region is a region in which the impurity concentration within the single-crystal semiconductor substrate is no less than 1×10¹⁷/cm³. Note that “region” in the present specification refers to a three-dimensional region having directionality in the direction of the surface of the substrate and in the direction that is perpendicular to the substrate.

In the single-crystal semiconductor film, a donor or an acceptor is formed through the implantation of an impurity element, for example, to form an impurity region. Typically, the impurity region is formed by implanting an impurity element in the direction of the film thickness, so a large amount of the impurity element will be found on the surface side, and the concentration will fall towards the surface on the opposite side, to form an impurity region having an impurity concentration gradient in the direction of film thickness. While there is no particular limitation on the impurity concentration in the impurity region having the impurity concentration gradient in the direction of the film thickness, preferably the impurity concentration varies in a range between 1×10¹⁷ and 1×10²¹/cm³.

The single-crystal silicon film is connected to a wiring from the face on the side wherein the impurity concentration is low, where the resistivity of the region to which the wiring is connected is no less than 1 μΩcm and no greater than 0.01 Ωcm. This makes it possible to obtain a low contact resistance and possible to obtain a stable contact, even when the wiring is connected to the single-crystal semiconductor film from the face on the side wherein the impurity concentration is low. Preferably, the resistivity is no less than 10 μΩcm and no more than 0.01 Ωcm.

The aforementioned “resistivity of the region to which the wiring is connected” is the resistivity of the single-crystal semiconductor film in the region of the connection between the single-crystal semiconductor film and the wiring when the single-crystal semiconductor film is viewed in a planar view. For example, when, as illustrated in FIG. 1, the wiring 33 includes a barrier metal layer 33a, and is connected to the single-crystal semiconductor film 29a, the resistivity of the single-crystal semiconductor film in the region on the face 47 in which the barrier layer 33a and the single-crystal semiconductor film 29a are connected should be no less than 1 μΩcm and no more than 0.01 Ωcm (note that, in FIG. 1, the wiring 33 includes the barrier metal layer 33a).

For the aforementioned “resistivity in the region to which the wiring is connected,” the resistivity can be calculated, for example, by the Van der Pauw method or the four-point-probe method, or from the impurity concentration measured using SIMS analysis. Additionally, preferably the thickness of the single-crystal semiconductor film in the region to which the wiring is connected is no less than, for example, 5 nm. Being no less than 5 nm enables good controllability and makes it possible to obtain a stable, low-resistance contact resistance.

Examples in which the resistivity of the region to which the wiring is connected is no less than 1 μΩcm and no more than 0.01 Ωcm include, for example: (1) example in which a region having a high impurity concentration is exposed by thinning the single-crystal semiconductor film so that the wiring contacts a region wherein the impurity concentration is high, and (2) example in which a hole is formed on the face on the side wherein the impurity concentration of the single-crystal silicon film is low, and the wiring is connected to the single-crystal semiconductor film through the hole.

Example (1) will be explained in greater detail. While in the single-crystal semiconductor film set forth above, the impurity concentration on the face on one side is different from the impurity concentration on the face on the other side, thinning the layer so that the resistivity on the face on the side wherein the impurity concentration is low becomes no less than 1 μΩcm and no more than 0.01 Ωcm makes it possible to obtain an excellent connection with a low contact resistance, even when the wiring is connected from the face on the side wherein the impurity concentration is low. This example can be fabricated easily by thinning the single-crystal semiconductor film.

In the case of Example (1), the resistivity of the region to which the wiring is connected can be obtained by measuring the resistivity at the surface of the single-crystal semiconductor film (the surface on the face on the side wherein the impurity concentration is low).

When the single-crystal semiconductor film is thinned and the single-crystal semiconductor film is used as the semiconductor portion for a thin-film transistor, preferably the thickness required to create the desired threshold voltage is thicker than the film thickness of the high-concentration impurity region. Here the high-concentration impurity region is the region in which the impurity concentration is high, formed on the face of the single-crystal semiconductor film on the side wherein the impurity concentration is high, and preferably is a region in which the impurity concentration is, for example, between 1×10¹⁹ and 1×10²¹/cm³.

Example (2), above wherein a hole is formed on the face of the single-crystal semiconductor film on the side wherein the impurity concentration is low and the wiring is connected to the single-crystal semiconductor film through this hole may be, for example, Example (2-1) in which, when the single-crystal semiconductor film is a single-crystal silicon film, a metal silicide portion is formed so as to reach from the face of the single-crystal semiconductor film on the side wherein the impurity concentration is low to a region in which the resistivity of the single-crystal semiconductor film is no less than 1 μΩcm and no more than 0.01 Ωcm, or Example (2-2) in which a portion of the surface of the face of the single-crystal semiconductor film on the side wherein the impurity concentration is low is removed to arrive at a region of the single-crystal semiconductor film wherein the resistivity is no less than 1 μΩcm and no more than 0.01 Ωcm, where the wiring is disposed in the removed portion. Moreover, there may also be Example (2-3) wherein a portion of the surface of the face of the single-crystal semiconductor film on the side wherein the impurity concentration is low is removed, and metal is disposed in the removed portion and caused to react with the silicon to form a metal silicide portion so as to access the region of the single-crystal semiconductor film wherein the resistivity is no less than 1 μΩcm and no more than 0.01 Ωcm (the embodiment illustrated in, for example, FIG. 29).

Merely connecting the wiring to the face on the side wherein the impurity concentration is low has a risk that the contact resistance between the wiring and the single-crystal semiconductor film will be high, causing the operation of the semiconductor element to be unstable. The provision of the hole in the face of the single-crystal semiconductor film on the side wherein the impurity concentration is low makes it possible to connect the wiring so as to arrive at the region in which the impurity concentration is high. Doing so makes it possible to reduce the contact resistance and to increase the stability. This also makes it possible to manufacture the semiconductor device with excellent repeatability.

In Example (1) described above, there is the danger that, if the thickness of the single-crystal semiconductor film is thinned too much, the semiconductor element will cease to be able to exhibit its full functionality. That is, in Example (1), not only is it necessary to maintain excellent characteristics such as the threshold voltage, and the like, for the thin-film transistors, but also necessary to adjust the impurity concentration within the single-crystal semiconductor film.

In the case of the semiconductor element being a thin-film transistor, the thickness of the single-crystal semiconductor film is a critical element that determines characteristics such as the threshold voltage, and thus it is difficult to make it too thin. In Example (2), the connection between the wiring and the single-crystal semiconductor film can be made to be a low-resistance, stable contact with the thickness of the single-crystal semiconductor film being a thickness that enables the desired threshold voltage. That is, preferably, a hole is made in the face of the single-crystal semiconductor film wherein the impurity concentration is low and the wiring is connected through the hole.

The aforementioned Example (2-1) will be explained in detail. When the single-crystal semiconductor film is a single-crystal silicon film, it is possible to form a metal silicide portion by reacting the silicon that forms the single-crystal semiconductor film with metal. Doing so makes it possible to make a stable connection by connecting this metal silicide portion with the region of the single-crystal silicon film wherein the resistivity is no less than 1 μΩcm and no more than 0.01 Ωcm.

Note that in the present specification, when a metal silicide portion is formed and the single-crystal semiconductor film and the wiring are connected through the metal silicide portion, the metal silicide portion forms only one portion of the wiring. Moreover, the metal silicide portion connects to the single-crystal semiconductor film from the face on the side wherein the impurity concentration is low, and is a part that includes no less than 20 at. % of a metal element other than silicon. This makes it possible to discriminate clearly between the single-crystal semiconductor film and the metal silicide portion. In this case, the resistivity of the portion wherein the wiring is connected is the resistivity of the region to which the metal silicide is connected. For example, in the case wherein a silicide portion 443 is formed as the tip end of the wiring 33, as illustrated in FIG. 29, the resistivity of the single-crystal semiconductor film at the face 347 that is the connecting part between the metal silicide portion 443 and the single-crystal semiconductor film 229a should be no less than 1 μΩcm and no more than 0.01 Ωcm.

The aforementioned Example (2-2) will be explained in more detail. In Example (2-2), a hole may be formed by removing a portion of the surface of the face of the single-crystal semiconductor film on the side wherein the impurity concentration is low, and a wiring that extends to the interior from the outside of the hole is provided so that the wiring is connected to the single-crystal semiconductor film within the hole. Doing so makes it possible to connect the wiring to the desired location in the single-crystal semiconductor film even when connecting from the side of the single-crystal semiconductor film wherein the impurity concentration is low, thus making it easy to reduce the contact resistance with the wiring. This makes it possible to structure a semiconductor element with superior characteristics. Note that the aforementioned “removal of a portion of the surface of the face of the single-crystal semiconductor film on the side wherein the impurity concentration is low” is the removal of a portion of the surface so that there will be a recessed portion in the surface of the single-crystal semiconductor film in the face on the side wherein the impurity concentration is low.

While in Example (2-1) described above, it is necessary to adjust the region in which the metal silicide portion is formed as well as the impurity concentration and the thickness of the semiconductor film into ranges in which the characteristics of the semiconductor elements will be acceptable, Example (2-2) described above can be used regardless of the thickness of the single-crystal semiconductor film and the distribution of the impurity concentration within the single-crystal semiconductor film. That is, preferably, the hole is formed by removing a portion from the face of the single-crystal semiconductor film on the side wherein the impurity concentration is low.

As described above, in Example (2-3), a portion of the surface of the single-crystal semiconductor film on the face having the low impurity concentration is removed, and metal is disposed and reacted with the silicon within the part that is removed, to form a silicide portion so as to access the region of the single-crystal semiconductor film wherein the resistivity is no less than 1 μΩcm and no more than 0.01 Ωcm. This makes it possible to adjust independently the thickness of the metal silicide and the depth when removing the portion of the surface on the face of the side wherein the impurity concentration is low, thus enabling use that is optimized to, for example, cases wherein the thickness of the single-crystal semiconductor film is thick.

The aforementioned hole is a recessed portion that is provided in the single-crystal semiconductor film, but does not penetrate all the way through the single-crystal semiconductor film. There is no particular limitation on the size of the hole, which should be set as appropriate depending on the characteristics of the single-crystal semiconductor film and on the structure and application of the semiconductor device to be fabricated.

The aforementioned “hole” is a recessed portion that is oriented towards the face of the single-crystal semiconductor film on the side wherein the impurity concentration is high from the face on the side wherein the impurity concentration is low, and a wiring is disposed within the hole. When the wiring and the single-crystal semiconductor film are connected by the metal silicide portion, the metal silicide portion that is formed within the hole is a portion of the wiring.

When the metal silicide portion is formed partially in the direction of the face of the single-crystal semiconductor film on the side wherein impurity concentration is high from the face of the single-crystal semiconductor film on the side wherein the impurity concentration is low, the portion of the single-crystal semiconductor film wherein the metal silicide portion is formed is viewed as the “hole.” For example, as illustrated in FIG. 32(a), a wiring 533 having a barrier metal layer 533a is connected to the opposite side of a single-crystal semiconductor film 529 from the high-concentration impurity region 522, and, as illustrated in FIG. 32(b), when the metal silicide portion 543 is formed through a heat treatment or the like of the barrier metal layer 533a, the space wherein the metal silicide portion 143 is formed is also viewed as the hole 532a in the single-crystal semiconductor film. In this case, the wiring 533 and the single-crystal semiconductor film 129 are connected through the hole 532a that is formed in the low-concentration impurity region 515.

While one may consider a variety of methods by which to fabricate the hole, preferably the hole is formed by removing a portion of the single-crystal semiconductor film from the face on the side wherein the impurity concentration is low. In the semiconductor device according to the present invention, the wiring is connected to a region of the single-crystal semiconductor film wherein the resistivity is no less than 1 μΩcm and no more than 0.01 Ωcm. That is, in the case wherein the aforementioned Example (2) is used, the hole accesses a region of the single-crystal semiconductor film wherein the resistivity is no less than 1 μΩcm and no more than 0.01 Ωcm.

The single-crystal silicon film described above preferably has an impurity concentration gradient wherein the impurity concentration becomes higher from the face on the one side wherein the impurity concentration is low towards the face on the other side wherein the impurity concentration is high, and preferably, the wiring is connected to the impurity region in which the impurity concentration of the single-crystal semiconductor film is no less than 1×10¹⁹/cm³ and no more than 1×10²¹/cm³. Doing so makes it possible to more reliably have a low contact resistance between the wiring and the single-crystal silicon film. Moreover, this enables an improvement in the stability of the contact and enables fabrication of the semiconductor device with greater repeatability.

When a hole is formed in the single-crystal semiconductor film, preferably that hole is provided up to a region of the single-crystal semiconductor film wherein the impurity concentration is no less than 1×10¹⁹/cm³ and no more than 1×10²¹/cm³. If the impurity concentration of the single-crystal semiconductor film were less than 1×10¹⁹/cm³, then the electric resistance would be comparable to the resistance between the source and the drain at the time of operation of the MOS transistor. Therefore, there would be the risk of a reduction in the ON current of the MOS transistor and a drop in the operating performance of the MOS transistor. Moreover, there is a relationship between the impurity concentration in the silicon and the resistivity. While this relationship depends also on the type of the impurity element, the lower limit of the impurity concentration in the case of implantation of boron or phosphorus into silicon, that is 1×10¹⁹/cm³, corresponds to the upper limit of 0.01 Ωcm for the resistivity. On the other hand, if the impurity concentration in the single-crystal semiconductor film were greater than 1×10²¹/cm³, then there would be the danger of separation of the impurity element due to being beyond the limit of solid solubility. The limit of solid solubility is the limit on the amount of the impurity element that can be dissolved within the crystal of the semiconductor. For example, the limit of solid solubility of boron, which is a P-type impurity element, in silicon is 6×10²⁰/cm³, and the limit of solid solubility of phosphorus, which is an N-type impurity element, in silicon is 1.5×10²¹/cm³.

The materials that structure the semiconductor device according to the present invention will be described in detail below. Preferably an insulating substrate, such as a glass substrate or a resin substrate like a plastic substrate, is used for the substrate. The semiconductor device according to the present invention is well-suited for use as one with a substrate that is used in a display device, such as a liquid crystal display device or an organic EL display, or the like (a display device substrate), because the glass substrate and the resin substrate are inexpensive when compared to quartz substrates and single-crystal semiconductor substrates, and the like, and can be made to be transparent.

The aforementioned substrate preferably is a glass substrate. A glass substrate has better thermal durability than a resin substrate, and heat treatments at about a medium-low temperature (for example, between 300 and 600° C.) can be performed on even a glass substrate. High-performance active circuits can be fabricated through combinations of active elements, such as polysilicon TFTs that are formed on the glass substrate, through medium-low temperature processes.

The substrate may preferably be a resin substrate. A resin substrate, because of its flexibility, enables a flexible semiconductor device, which is well-suited to use in a variety of applications. Moreover, it is also able to prevent cracking, and the like, resulting from physical shock.

The resin substrate preferably is a plastic substrate. A plastic substrate has superior flexibility, and is more lightweight than a glass substrate, making it well-suited for a variety of applications, such as in mobile devices, and the like.

As a method for manufacturing the aforementioned semiconductor device, preferably, a semiconductor element, or a portion thereof, formed on a single-crystal semiconductor substrate, may be transferred onto an intermediate substrate, and a heat treatment is performed on the semiconductor element, or the portion thereof, which is on the intermediate substrate. This is because performing the heat treatment on the intermediate substrate enables the heat treatment to be performed at a higher temperature, even when a glass substrate or a plastic substrate having poor thermal durability is used as the substrate. From this perspective, the semiconductor device according to the present invention is particularly well-suited in cases where the aforementioned substrate is a glass substrate or a resin substrate.

While there is no particular limitation thereon, a variety of single-crystal semiconductors can be used as the material for the single-crystal semiconductor film. For example, as a preferred form of the aforementioned single-crystal semiconductor film, a preferred form would include at least one selection from a group including group IV semiconductors, group II-VI compound semiconductors, group III-V compound semiconductors, group IV-IV compound semiconductors, and mixed crystals containing elements belonging to those same groups.

The aforementioned group IV semiconductor may be, for example, diamond, silicon, germanium, or the like. The group IV-IV compound semiconductor may be, for example, silicon carbide (SiC), silicon germanium (SiGe), or the like. The aforementioned group II-VI compound semiconductor is a semiconductor that combines a group II element and a group VI element, and may be, for example, zinc oxide (ZnO), cadmium telluride (CdTe), or zinc selenite (ZnSe). The aforementioned group III-V compound semiconductors are semiconductors that combine group III elements and group V elements, and include gallium arsenide (GaAs), gallium nitride (GaN), aluminum nitride (AlN), indium phosphide (InP), and indium nitride (InN). The aforementioned “a mixed crystal including these same elements” is, for example, in the case of the group IV semiconductor, a structure that is a single-crystal wherein there is a mixture of another group IV element in addition to the element that is structured as the primary group IV semiconductor. In the case of the group II-VI compound semiconductor, a single crystal mixture of another group II element and/or group VI element is/are mixed into the group II and group VI elements that primarily structure the group II-VI compound semiconductor.

Preferred forms of the single-crystal semiconductor film include a group IV semiconductor, and include a form wherein the group IV semiconductor is silicon. The single-crystal silicon semiconductor is well-suited in terms of being inexpensive when compared to other single-crystal semiconductors, and in terms of the ability to fabricate a semiconductor element having stable characteristics when made into a semiconductor element, such as a transistor.

There are no particular limitations on the aforementioned wiring as long as a material that has conductivity is used. For example, a transparent electrically conductive material or an electrically conductive oxide, or the like, may be used. Preferable forms include metal materials with low resistances. Low-resistance metal materials include aluminum, molybdenum, tungsten, copper, and the like. That is, preferred forms of the wirings include one or more selections from a group including aluminum, molybdenum, tungsten, and copper. Doing so makes it possible to keep the wiring resistance low, making it possible to avoid wiring delays, voltage drops due to resistance, and the like.

The aforementioned semiconductor elements include: power supply rectifying diodes, fixed-voltage diodes (Zener diodes), variable capacitance diodes, PIN diodes, Schottky barrier diodes (SBDs), solar cells, surge-protecting diodes, diacts, varistors, Esaki diodes (tunnel diodes), PN-junction diodes, and other two-terminal elements (diodes); light-emitting diodes (LEDs), laser diodes, semiconductor lasers, photodiodes, charge-coupled devices (CCDs), and other photonic devices; and bipolar transistors, Darlington transistors, field-effect transistors (FETs), insulated-gate bipolar transistors (IGBTs), unijunction transistors (UJTs), phototransistors, SI transistors (static inductance transistors) thyristors (SCRs), gate turn-off thyristors (GTOs), triacts, light-triggered thyristors (LTTs), SI thyristors (static inductance thyristors), junction transistors, and other three-terminal elements (transistors).

The structure of the semiconductor device according to the present invention has no particular limitations, and may or may not include another structural element. For example, there may be, on the substrate, a transistor that includes a non-single-crystal semiconductor thin film and that does not include a single-crystal semiconductor film. When the semiconductor device according to the present invention is used as a substrate for a display device, members for achieving the display, such as pixel electrodes, or the like may be provided.

Preferred forms of embodiments of the semiconductor device according to the present invention will be explained in greater detail below.

The semiconductor element is a transistor having a single-crystal semiconductor film, a gate insulating film, and a gate electrode layered in that order, wherein preferably the single-crystal semiconductor film has a gate insulating film on the face on the side wherein the impurity concentration is high, and wirings are connected to the source region and the drain region of the transistor. The transistor is typically a field-effect transistor (FET), wherein the electric current that flows in the single-crystal semiconductor film is controlled by the voltage that is applied to the gate electrode.

If the single-crystal semiconductor film has a gate insulating film on the face having the high impurity concentration, the wirings are connected from the face of the single-crystal semiconductor film on the side that is opposite from the gate insulating film. Further, the wiring and the single-crystal semiconductor film may be connected through a hole, where preferably a hole is provided in the source region and/or the drain region of the transistor. In this case, the hole is provided on the face that is on the side that is opposite from the gate insulating film.

In the above transistor, wirings are connected to the single-crystal semiconductor film in the source region and the drain region. In this case, the wirings are the source wiring and the drain wiring.

In the manufacturing of a typical transistor, the N-type impurity region and the P-type impurity region, and the like, are formed through implantation of impurity elements from the gate insulator film side of the single-crystal semiconductor film; however, because the impurity elements are implanted from one direction of the single-crystal semiconductor film, the impurity concentration will be low on the opposite side from the side that is implanted (the side that is opposite from the gate insulating film). In this case, if the wiring were merely connected to the face on the side wherein the impurity concentration is low, then the contact resistance would be increased, with the risk that it may not be possible to obtain acceptable transistor characteristics. Given this, connecting the wiring to a region of the single-crystal semiconductor film wherein the resistivity is no less than 1 μΩcm and no more than 0.01 Ωcm, as in the present invention, makes it possible to reduce the resistance of the contact connection, and to increase the stability of the contact resistance. This makes it possible to manufacture, with excellent repeatability, a semiconductor device that has a transistor.

The aforementioned transistor may be one wherein a single-crystal semiconductor film, a gate insulating film, and a gate electrode are layered in that order. The single-crystal semiconductor film, the gate insulating film, and the gate electrode may be lined up in that order from the substrate side. Or, the gate electrode, the gate insulating film, and the single-crystal semiconductor film may be lined up in that order from the substrate side. A method in which a semiconductor element that is formed on a single-crystal semiconductor substrate is transferred onto an intermediate substrate, an interconnecting layer is formed on the intermediate substrate, and then it is transferred onto a substrate such as a glass substrate is preferable for use in manufacturing of the semiconductor device according to the present invention. From the perspective of manufacturing using this method wherein the transfer is performed twice, preferably the single-crystal semiconductor film and the gate insulating film and gate electrode are layered from the substrate side in that order. If, for convenience in the manufacturing process, the transfer of the semiconductor element is performed three or more times, then the sequence from the substrate side may be reversed.

One may consider a method for connecting the wiring and the single-crystal semiconductor film in the transistor, wherein, as described above, the wiring is connected to a region with a high impurity concentration by thinning the single-crystal silicon film. The method wherein the single-crystal semiconductor film is thinned is effective when the thickness of the high-concentration impurity region that is the source region or the drain region is thick when compared to the desired film thickness for the channel portion of the transistor. However, because there is the risk that the transistor will not be able to produce acceptable characteristics if the thickness of the single-crystal semiconductor film is too thin, Example (2) described above is preferable as the form for connecting the wiring and the single-crystal semiconductor film.

In the transistor, an insulating film may be provided on the opposite side of the single-crystal semiconductor film from the gate insulating film, and the wiring and the single-crystal semiconductor film may be connected through a contact hole that is formed in the insulating film. This makes it possible to form simultaneously the contact holes and the holes that are formed in the single-crystal semiconductor film. In order for the wiring to connect to the single-crystal semiconductor film through the holes that are provided, preferably the holes are provided in regions that, when the semiconductor device is viewed in a planar view, overlap the contact holes that are formed in the insulating film, disposed on the side that is opposite from the gate insulating film.

The transistor described above preferably has side walls on the faces on the gate electrode side. The single-crystal semiconductor film preferably has a low-concentration impurity region and a high-concentration impurity region that has an impurity concentration higher than that of the low-concentration impurity region. The gate electrode preferably is self-aligning with the channel region of the semiconductor layer, and preferably the side walls are self aligning with the low-concentration impurity region. Preferably, the low-concentration impurity region is formed between the high-concentration impurity region and the channel region. Such a structure includes, for example, a structure wherein the single-crystal semiconductor film has a high-concentration impurity region that is adjacent to the outside of the low-concentration impurity region (on the side that is opposite from the channel region) in the single-crystal semiconductor film, as in the semiconductor device illustrated in FIG. 1. Thus, the structure may be an LDD structure wherein, as illustrated in FIG. 1, channel regions 45a and 45b are formed in the single-crystal semiconductor film 29a, low-concentration impurity regions are formed on the channel region 45a and 45b sides of the source/drain regions 46a or 46b, and high-concentration impurity regions are formed to the outside of the low-concentration impurity regions. In this way, a channel region, low-concentration impurity region, and high-concentration impurity region can be formed self-aligning to the gate electrode and the side walls to form an LDD structure with ease without using the resist or the like. This not only enables the achievement of improved productivity, but also the achievement of an improvement in the transistor characteristics. Note that the low-concentration impurity region is a region in which the impurity concentration is lower than that of the high-concentration impurity region. While there are no particular limitations on the impurity concentrations in the low-concentration impurity regions, preferably they are in the range of, for example, 1×10¹⁸ to 1×10¹⁹/cm³. Additionally, preferably the impurity concentration in the high-concentration impurity region is in the range of 1×10¹⁹ to 1×10²¹/cm³. Note that in the present specification, the channel region is a region in which a channel is formed in the single-crystal semiconductor film, and a source/drain region is regions that serve as both or either source region and/or drain region.

Preferably, in the aforementioned transistor, the high-concentration impurity region and the wiring are connected. Doing so connects the wiring to the region in which the impurity concentration is high, thus enabling a reduction in the contact resistance between the wiring and the single-crystal semiconductor film.

When, as described above, the single-crystal semiconductor film has a low-concentration impurity region and a high-concentration impurity region, preferably the high-concentration impurity region has an impurity concentration gradient in the direction of the film thickness, so that within the high-concentration impurity region, the side of the single-crystal semiconductor film wherein the impurity concentration is high will be the side of the high-concentration impurity region in which the impurity concentration is high. Additionally, the connection of the high-concentration impurity region and the wiring is formed from the side of the high-concentration impurity region in which the impurity concentration is low.

Preferred forms of embodiments of the signal-crystal semiconductor film include a form having a metal silicide layer on the surface of the source region and/or drain region on the gate insulating film side. In doing so, an electric current path is formed from the source region and the drain region to the channel region, more effectively enabling a reduction in the parasitic resistance. For example, a metal silicide layer 242 may be formed on the surface of the high-concentration impurity region 22 or 25 on the gate electrode side of the transistor, as in the semiconductor device illustrated in FIG. 27. The use of this structure causes the high-concentration impurity region 22 or 25 to be connected electrically to the low-resistance metal silicide layer 242 through an extremely short distance in the direction of film thickness, from the metal wiring 33, forming an electric current path to the channel region of the NMOS or PMOS transistor, thus enabling a more effective reduction in parasitic resistance. When, as described above, the high-concentration impurity region is provided at the source region of the transistor, the provision is in the sequence of the metal silicide layer and the high-concentration impurity region, from the face of the single-crystal semiconductor film on the side wherein the impurity concentration is high. Note that in the present specification, the “metal silicide layer” is viewed as a separate material, not a portion of the single-crystal semiconductor film. The “metal silicide layer” is a layer made from a silicide that is formed on the face of the single-crystal semiconductor film on the side wherein the impurity concentration is high, and the “metal silicide portion” is a part that is made out of silicide that is formed by the face of the single-crystal semiconductor film on the side wherein the impurity concentration is low, so there is a clear distinction. Moreover, the metal silicide layer is a layer that includes no less than 20 at. % of a metal element other than silicon.

The single-crystal semiconductor film preferably has a metal silicide portion within the hole. This results in the tip of the wiring being made from a metal silicide portion, enabling the connection of the metal silicide portion to the single-crystal semiconductor film, thus enabling a reduction in the resistance between the wiring and the single-crystal semiconductor film. For example, the metal silicide portion may be formed through depositing a metal material onto the surface of the single-crystal semiconductor film or into a recessed portion that is formed through removing a portion of the surface of the single-crystal semiconductor film, from the face of the single-crystal semiconductor film on the side wherein the impurity concentration is low, with the silicon diffusing into the metal material through heating or the like. As a result, the resistance between the metal silicide formed in this way and the single-crystal semiconductor film becomes low. Also, the metal silicide portion becomes the tip portion of the wiring, so the contact resistance between the metal silicide portion and the metal material that structures the wiring will be low when compared to a case of a connection between the single-crystal semiconductor film or the like, and the metal material that forms the wiring. This makes it possible to obtain a stable contact resistance. This also makes it possible to suppress the operating delays and the like, which are caused by the contact resistance. Note that the “interior of the hole” or “inside of the hole” means the space that is recessed relative to the surface of the single-crystal semiconductor film.

The metal silicide portion preferably includes at least one selected from a group including titanium, nickel, and cobalt. Doing so makes it possible to obtain a stable contact resistance at an even lower resistance.

Preferably, the aforementioned wiring has a barrier metal layer including at least one selected from a group including titanium nitride and tantalum nitride. Doing so makes it possible to prevent the materials that structure the wiring from diffusing into the materials that contact the wiring, even when a heat treatment is performed. The barrier metal layer is a layer that is provided so that the materials that structure the wiring will not diffuse into the insulating film or the like. Metal materials with low resistances such as, for example, aluminum, molybdenum, tungsten, and copper, which are well-suited for use as the materials for structuring the wiring, easily diffuse into the insulating film and the like, through heating or the like. Given this, the wiring having a barrier metal layer makes it possible to suppress the diffusion of the metal material that structures the wiring, even when there is a heat treatment or the like, because the surface of the wiring that contacts the insulating film is the barrier metal layer when, for example, the wiring has an insulating film on the side of the single-crystal semiconductor film that is opposite to the gate insulating film and the wiring is connected to the single-crystal semiconductor film through a contact hole that is provided in the insulating film. Moreover, an extreme increase in contact resistance due to the formation of spikes through the diffusion, into the silicon, of metal materials, such as aluminum, can be prevented by the barrier metal layer. Note that the spikes are a phenomenon wherein silicon diffuses into a metal material, such as aluminum, at the contacting portion of the metal material and silicon (Si), polycrystalline silicon (poly-Si) or the like, and the metal material precipitates at the locations where silicon has been removed.

The aforementioned semiconductor device preferably has an interlayer insulating film on the side of the single-crystal semiconductor film wherein the impurity concentration is low. Preferably, a contact hole is formed in the interlayer insulating film, and a plug contact is formed by filling the contact hole with tungsten. Doing so enables the formation of devices with low resistance and high density.

As an example wherein a tungsten plug contact is formed, as shown in FIG. 33, an interlayer insulating film 631 is disposed on the side of the single-crystal semiconductor layer 629 wherein the impurity concentration is low, a contact hole 632 is provided at the part wherein the wiring 633 and the single-crystal semiconductor film 629 are connected, and the contact hole 632 is filled with tungsten 633b, as shown in the schematic cross-sectional diagram. In this case, preferably a barrier metal layer 633a is disposed on the wall surfaces of the contact hole.

Preferably, the semiconductor device set forth above includes at least one of an NMOS transistor or a PMOS transistor. Moreover, preferably, the semiconductor device includes an NMOS transistor and a PMOS transistor. An NMOS transistor is a MOS transistor wherein the source region and the drain region are of N-type semiconductor, and a PMOS transistor is an MOS transistor wherein the source region and the drain region are of P-type semiconductor. A CMOS transistor can be made through the use of an NMOS transistor and a PMOS transistor, which can be used suitably in a variety of circuits.

The single-crystal semiconductor film preferably is peeled at a peeling layer that includes a peeling substance, formed in a single-crystal semiconductor substrate. That is, preferably, the single-crystal semiconductor film is a portion of a single-crystal semiconductor substrate, peeled at a peeling layer. When separating a portion from a single-crystal semiconductor substrate, the single-crystal semiconductor film can be separated relatively easily through the use of a method wherein a peeling layer is formed by implanting a peeling substance into the semiconductor substrate and then separating at the peeling layer. The crystallinity of the single-crystal semiconductor breaks down at the peeling layer that is formed by implanting the peeling substance, causing that portion to be brittle, thereby enabling the separation. While methods that use chemical polishing and chemical-mechanical polishing, and that use porous silicon, are used as methods for manufacturing SOI substrates, the present method is a simple manufacturing method because no polishing, or the like, is required. An improvement in productivity can be achieved through the use of this method.

Preferably, the peeling substance includes at least one of hydrogen or an inert gas element. While all that is necessary is for the peeling substance to form a peeling layer in the single-crystal semiconductor substrate, preferably it contains at least one of hydrogen or an inert gas element. The inert gas element may be, for example, nitrogen or a noble gas element such as helium, argon, xenon, krypton, or the like.

The present invention is also a semiconductor device having, on a substrate, a single-crystal semiconductor film and a semiconductor element that includes a wiring that is connected to the single-crystal semiconductor film, wherein: the semiconductor element is a transistor wherein a single-crystal semiconductor film, a gate insulating film, and a gate electrode are layered in that order; wherein, in the single-crystal semiconductor film, the impurity concentration on the face on one side is different from the impurity concentration on the face on the other side, and has a gate insulating film on the face on the side wherein the impurity concentration is high; wirings are connected to a source region and a drain region of the transistor from the face on the side wherein the impurity concentration is low; the single-crystal semiconductor film has a metal silicide layer at the surface on the gate insulating film side of the source region and/or the drain region; and the metal silicide layer is connected to a wiring and the resistivity of the region to which the wiring is connected is no less than 1 μΩcm and no more than 0.01 Ωcm (hereinafter termed the “second semiconductor device” according to the present invention). This makes it possible to reduce further the parasitic resistance of the electric current path to the channel region. Preferably the resistivity of the regions to which the wirings are connected is no less than 10 μΩcm and no more than 0.01 Ωcm.

For example, as in the semiconductor device illustrated in FIG. 28, a structure in which a silicide layer 342 is formed on the surface of the gate electrode side of a high-concentration impurity region 22 or 25 of an MOS transistor and the wiring is connected to the metal silicide layer 342 is preferable. The use of such a form enables a further reduction in the parasitic resistance of the electric current path to the channel region of the transistor.

Note that when it comes to the aforementioned resistivity, the resistivity of the region in which the wiring is connected to the metal silicide layer may be difficult to measure, and in such a case, the resistivity of a region that has essentially the same resistivity as that of the metal silicide layer that is connected to the wiring should be measured.

In the second semiconductor device according to the present invention, the following variations are possible, in the same manner as described for the first semiconductor device according to the present invention:

(1) The single-crystal semiconductor film is provided with a hole in the face on the side wherein the impurity concentration is low, and the wiring is connected to the metal silicide layer through this hole.

(2) The hole is formed through the removal of a portion from the face of the single-crystal semiconductor film on the side wherein the impurity concentration is low.

(3) The transistor has side walls on the faces on the sides of the gate electrode; the single-crystal semiconductor film has a low-concentration impurity region, and a high-concentration impurity region that has an impurity concentration higher than that of the low-concentration impurity region; the gate electrode is self-aligning with the semiconductor layer channel region; the side wall is self-aligning with the low-concentration impurity region; and the low-concentration impurity region is formed between a high-concentration impurity region and the channel region.

(4) The single-crystal semiconductor film has an impurity gradient from the face on the one side wherein the impurity concentration is low towards the face on the other side wherein the impurity concentration is high, where the hole is provided to the region of the single-crystal semiconductor film wherein the impurity concentration is no more than 1×10¹⁹/cm³ and no less than 1×10²¹/cm³. In this case, the wiring is connected to the metal silicide layer, and thus the impurity concentration should be measured at a depth that is essentially identical to the depth of the single-crystal semiconductor film wherein the hole is provided.

(5) The single-crystal semiconductor film has a metal silicide portion within the hole. In this case, the metal silicide portion and the metal silicide layer are connected. The differences in materials, the shapes, the compositions, and the like of the metal silicide portion and the metal silicide layer can be discerned through transmission electron microscope (TEM) observation, elemental analysis, or the like.

(6) The metal silicide portion includes at least one selected from a group including titanium, nickel, and cobalt.

(7) The wiring includes at least one selected from a group including aluminum, molybdenum, tungsten, and copper.

(8) The wiring has a barrier metal layer that includes at least one selected from a group including titanium, titanium nitride, and tantalum nitride.

(9) The semiconductor device has an interlayer insulating film on the side of the single-crystal semiconductor film wherein the impurity concentration is low, a contact hole is formed in the interlayer insulating film, and the wiring has a plug contact wherein the contact hole is filled with tungsten.

(10) The single-crystal semiconductor film includes at least one selected from a group including a group IV semiconductor, a group II-VI compound semiconductor, a group III-V compound semiconductor, a group IV-IV compound semiconductor, and a mixed crystal containing elements of these same groups.

(11) The single-crystal semiconductor film includes a group IV semiconductor, and the group IV semiconductor is silicon.

(12) The substrate is a glass substrate.

(13) The substrate is a resin substrate.

(14) The semiconductor device includes at least one of an NMOS transistor and a PMOS transistor.

(15) The single-crystal semiconductor film is peeled at a peeling layer that includes a peeling substance, formed in a single-crystal semiconductor substrate.

(16) The peeling substance includes hydrogen and/or an inert gas element.

The use of the aforementioned forms (1) to (16) enables a semiconductor device with superior characteristics in the second semiconductor device according to the present invention in the same manner as in the first semiconductor device according to the present invention.

The present invention is further a method for manufacturing the first or second semiconductor device, including: a step of transferring to an intermediate substrate a semiconductor element or a portion thereof, formed in a single-crystal semiconductor substrate; and a step of transferring the semiconductor element or a portion thereof, from the intermediate substrate to a substrate. Transferring the semiconductor element from the single-crystal semiconductor substrate to the intermediate substrate enables processes that are not possible when performed on a glass substrate. This makes it possible to improve the characteristics of the semiconductor element. For example, performing a high temperature heat treatment or the like, after transferring the semiconductor element or the portion of the semiconductor element from the single-crystal semiconductor substrates to the intermediate substrate makes it possible to eliminate the thermal donors and the like within the single-crystal semiconductor film, making it possible to improve the operating stability of the transistor. Furthermore, a method wherein the semiconductor element or the portion thereof is transferred onto an intermediate substrate and a heat treatment is performed on the intermediate substrate is particularly well-suited for use. In this manufacturing step, the high temperature heat treatment can be performed on the intermediate substrate, and thus this is particularly suitable when using a substrate having poor thermal durability, such as a glass substrate or a resin substrate, as the substrate for structuring the semiconductor device. That is, preferably the single-crystal semiconductor film is first transferred to the intermediate substrate from the single-crystal semiconductor substrate, after which the heat treatment is performed on the intermediate substrate, following which there is yet another transfer from the intermediate substrate to a glass substrate or a resin substrate.

Preferably, the intermediate substrate is a substrate of higher thermal durability than an insulating substrate. Moreover, the intermediate substrate may have a separating layer for separating at a prescribed depth. Doing so enables the easy removal of the intermediate substrate after bonding of the single-crystal semiconductor element or the single-crystal semiconductor film onto the insulating substrate, which is the final substrate.

The intermediate substrate may have, at its surface, a bonding structure wherein multiple regions are partially opened, and the separating layer may have a structure wherein a portion of the intermediate substrate is removed through etching from the plurality of openings of the bonding structure. Doing so makes it possible to remove the intermediate substrate more easily after the single-crystal semiconductor element or single-crystal semiconductor film is bonded onto the substrate that is the final substrate. Note that a columnar structure having a plurality of column portions is well-suited as the bonding structure. On the other hand, the separating layer may be an alloy layer of germanium and silicon. This also makes it possible to remove the intermediate substrate more easily after bonding of the single-crystal semiconductor element or the single-crystal semiconductor film onto the substrate that is the final substrate.

The manufacturing method set forth above preferably includes a step for a heat treatment of the semiconductor element that is disposed on the intermediate substrate. Doing so enables the heat treatment to be performed at a high temperature, enabling an improvement in the characteristics of the semiconductor element. For example, when the single-crystal semiconductor film is obtained by forming a peeling layer through implanting, into a single-crystal semiconductor substrate, a peeling substance, such as hydrogen ions, and then peeling at the peeling layer, the crystallinity of the single-crystal semiconductor film will be reduced through the implantation, and thus preferably the characteristics are restored through the performance of a heat treatment. If a heat treatment were performed on a substrate with low thermal durability, such as a glass substrate, the temperature of the heat treatment could not be a high temperature, which has sometimes made it susceptible to thermal donors and made it impossible to adequately restore the characteristics of the transistor resulting from the deactivation of the boron (B), which is an acceptor. Given this, after the semiconductor element is transferred onto the intermediate substrate that has a higher thermal durability than a substrate such as a glass substrate, the heat treatment is performed on the intermediate substrate, after which the semiconductor element is transferred from the intermediate substrate to a substrate such as a glass substrate, thereby making it possible to produce a semiconductor device having a semiconductor element with superior transistor characteristics.

Preferably, this manufacturing process includes a step for forming wirings after the step for performing the heat treatment on the portion of the semiconductor element that is disposed on the intermediate substrate. In the method for manufacturing the semiconductor device according to the present invention, a step of performing a heat treatment on the intermediate substrate is preferably included. However, if the heat treatment is performed at a high temperature, then if the wirings were formed prior to performing that high-temperature heat treatment, there would be the risk that the materials from which the wirings are formed would diffuse into the materials that structure the semiconductor device. Therefore, by forming the wirings after performing the high-temperature heat treatment, it is possible to suppress the diffusion of the materials that form the wirings thereby making it possible to improve the operating stability of the semiconductor device.

### Effects of the Invention

The first and second semiconductor devices according to the present invention form semiconductor elements having low-resistance and stable contact connections, even when the wirings are connected from the side of the single-crystal semiconductor film in which the impurity concentration is low. Moreover, a semiconductor device having this type of semiconductor element can be formed by first transferring a semiconductor element, or a portion thereof, that is formed in a single-crystal semiconductor substrate onto an intermediate substrate, and then placing it on a glass substrate, or the like, so a high-temperature heat treatment that cannot be performed on a substrate having low thermal durability, such as a glass substrate, can be performed on the intermediate substrate, thus enabling a semiconductor device having superior transistor characteristics. This type of semiconductor device can be used as a variety of different devices that require circuits, and is well-suited for use as, for example, a substrate for a display device, such as a liquid crystal display device, an organic EL display device, or the like.

### BRIEF DESCRIPTION OF THE DRAWINGS

FIG. 1 is a schematic cross-sectional diagram illustrating the structure of a semiconductor device according to Embodiment 1.

FIG. 2 is a schematic cross-sectional diagram illustrating the manufacturing flow for the semiconductor device according to Embodiment 1 (for forming a thermal oxide film).

FIG. 3 is a schematic cross-sectional diagram illustrating the manufacturing flow for the semiconductor device according to Embodiment 1 (for implanting an impurity element).

FIG. 4 is a schematic cross-sectional diagram illustrating the manufacturing flow for the semiconductor device according to Embodiment 1 (for implanting an impurity element).

FIG. 5 is a schematic cross-sectional diagram illustrating the manufacturing flow for the semiconductor device according to Embodiment 1 (for forming an N-well region, a P-well region, and a thermal oxide film).

FIG. 6 is a schematic cross-sectional diagram illustrating the manufacturing flow for the semiconductor device according to Embodiment 1 (for patterning a silicon nitride film and a thermal oxide film)

FIG. 7 is a schematic cross-sectional diagram illustrating the manufacturing flow for the semiconductor device according to Embodiment 1 (for forming a LOCOS oxide film).

FIG. 8 is a schematic cross-sectional diagram illustrating the manufacturing flow for the semiconductor device according to Embodiment 1 (for forming a gate insulating film).

FIG. 9 is a schematic cross-sectional diagram illustrating the manufacturing flow for the semiconductor device according to Embodiment 1 (for forming a gate electrode).

FIG. 10 is a schematic cross-sectional diagram illustrating the manufacturing flow for the semiconductor device according to Embodiment 1 (for forming an N-type low-concentration impurity region).

FIG. 11 is a schematic cross-sectional diagram illustrating the manufacturing flow for the semiconductor device according to Embodiment 1 (for forming a P-type low-concentration impurity region).

FIG. 12 is a schematic cross-sectional diagram illustrating the manufacturing flow for the semiconductor device according to Embodiment 1 (for forming side walls).

FIG. 13 is a schematic cross-sectional diagram illustrating the manufacturing flow for the semiconductor device according to Embodiment 1 (for forming an N-type high-concentration impurity region).

FIG. 14 is a schematic cross-sectional diagram illustrating the manufacturing flow for the semiconductor device according to Embodiment 1 (for forming a P-type high-concentration impurity region).

FIG. 15 is a schematic cross-sectional diagram illustrating the manufacturing flow for the semiconductor device according to Embodiment 1 (for forming a planarizing film).

FIG. 16 is a schematic cross-sectional diagram illustrating the manufacturing flow for the semiconductor device according to Embodiment 1 (for forming a peeling layer).

FIG. 17 is a schematic cross-sectional diagram illustrating the manufacturing flow for the semiconductor device according to Embodiment 1 (for bonding to an intermediate substrate).

FIG. 18 is a schematic cross-sectional diagram illustrating the manufacturing flow for the semiconductor device according to Embodiment 1 (for peeling the single-crystal semiconductor film using the peeling layer).

FIG. 19 is a schematic cross-sectional diagram illustrating the manufacturing flow for the semiconductor device according to Embodiment 1 (for a polishing process).

FIG. 20 is a schematic cross-sectional diagram illustrating the manufacturing flow for the semiconductor device according to Embodiment 1 (for forming an SiO₂ film).

FIG. 21 is a schematic cross-sectional diagram illustrating the manufacturing flow for the semiconductor device according to Embodiment 1 (for forming an interlayer insulating film).

FIG. 22 is a schematic cross-sectional diagram illustrating the manufacturing flow for the semiconductor device according to Embodiment 1 (for forming contact holes and holes to the single-crystal semiconductor film).

FIG. 23 is a schematic cross-sectional diagram illustrating the manufacturing flow for the semiconductor device according to Embodiment 1 (for forming a metal wiring).

FIG. 24 is a schematic cross-sectional diagram illustrating the manufacturing flow for the semiconductor device according to Embodiment 1 (for forming a planarizing film).

FIG. 25 is a schematic cross-sectional diagram illustrating the manufacturing flow for the semiconductor device according to Embodiment 1 (for bonding to a glass substrate).

FIG. 26 is a schematic cross-sectional diagram illustrating the manufacturing flow for the semiconductor device according to Embodiment 1 (for separating from the intermediate substrate).

FIG. 27 is a schematic cross-sectional diagram illustrating the state of being bonded to the intermediate substrate in a manufacturing process for a semiconductor device according to Embodiment 2.

FIG. 28 is a schematic cross-sectional diagram illustrating the state of being bonded to the intermediate substrate in a manufacturing process for a semiconductor device according to Embodiment 3.

FIG. 29 is a schematic cross-sectional diagram illustrating the state of being bonded to the intermediate substrate in a manufacturing process for a semiconductor device according to Embodiment 4.

FIG. 30(a) is a schematic planar view illustrating the structures of the manufacturing processes for an intermediate substrate for Embodiments 1 through 3, and FIG. 30(b) is a schematic cross-sectional diagram sectioned at the line X1-X2. 30

FIG. 31(a) is a schematic planar view illustrating the structures of an intermediate substrate for Embodiments 1 through 3, and FIG. 31(b) is a schematic cross-sectional diagram sectioned at the line X1-X2.

FIG. 32 is a schematic cross-sectional diagram illustrating the state in which the single-crystal semiconductor film and the wiring are connected at a silicide portion in a semiconductor device according to the present invention. FIG. 32(a) illustrates the state prior to the formation of the silicide portion, and FIG. 32(b) illustrates the state after the formation of the silicide portion.

FIG. 33 is a schematic cross-sectional diagram illustrating the state in which a tungsten plug contact has been formed when connecting the single-crystal semiconductor film and the wiring in a semiconductor device according to the present invention.

### DETAILED DESCRIPTION OF THE EMBODIMENTS

Embodiments will be presented below, and the present invention will be explained in further detail in reference to the drawings; however, the present invention is not limited to only these embodiments.

### Embodiment 1

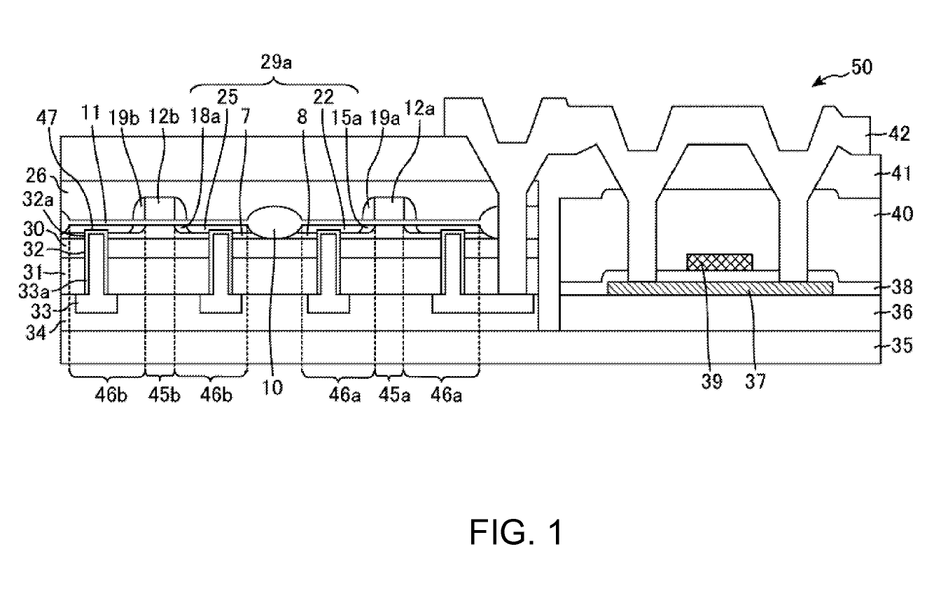

FIG. 1 is a schematic cross-sectional diagram illustrating the structure of a semiconductor device according to Embodiment 1. As illustrated in FIG. 1, a semiconductor chip having a semiconductor element that includes a single-crystal semiconductor film 29a, obtained through peeling a portion of a single-crystal silicon substrate, and a thin-film transistor formed directly on the substrate, including a gate electrode 39, a gate insulating film 38, and a non-single-crystal semiconductor layer 37, are disposed on a substrate 35 in a semiconductor device 50.

In the semiconductor chip, a planarizing film 34, an interlayer insulating film 31, and an SiO₂ film 30 are layered from the substrate 35 side, and the single-crystal semiconductor film 29a is placed thereon. A gate insulating film 11 is disposed on top of the single-crystal semiconductor film 29a, and gate electrodes 12a and 12b are disposed thereon. Sidewalls 19a and 19b are provided on the side faces of the gate electrodes 12a and 12b. A planarizing film 26 and an interlayer insulating film 41 are provided on the top thereof. Moreover, a metal wiring 42 is provided through a contact hole that is provided so as to reach from above the interlayer insulating film 41 to the metal wiring 33.

The single-crystal semiconductor film 29a has a channel region 45a that is self-aligned with the gate electrode 12a, N-type low-concentration impurity regions 15a that are self-aligned to the side walls 19a, and N-type high-concentration impurity regions 22 that are formed on the sides of the N-type low-concentration impurity regions 15a that are opposite from the channel regions 45a. An NMOS transistor is formed thereby. Moreover, the single-crystal semiconductor film 29a has a channel region 45b that is self-aligned to the gate electrode 12b, N-type low-concentration impurity regions 18a that are self-aligned to the side walls 19b, and P-type high-concentration impurity regions 25 that are formed in the N-type low-concentration impurity regions 18a on the sides opposite from the channel region 45b. A PMOS transistor is formed thereby. A LOCOS oxide film 10 that is integral with the gate oxide film is provided in order to isolate between the NMOS transistor and the PMOS transistor.

Additionally, contact holes 32 are provided penetrating through the interlayer insulating film 31 and the SiO₂ film 30, and holes 32a are provided in the single-crystal semiconductor film in an extension of these contact holes. Metal wirings 33 are provided so as to fill these contact holes 32 and holes 32a, and the metal wirings 33 are connected to the single-crystal semiconductor film 29a. The metal wirings 33 are provided with a barrier metal layer 33a along the wall faces and bottom faces of the contact holes 32 and holes 32a, suppressing the diffusion of the metal materials that structure the metal wirings 33.

Here, the resistivity at the contact surface 47 between the tip end of the barrier metal layer 33a, which is a portion of the wiring 33, and the single-crystal semiconductor film 29a is set to between 0.01 Ωcm and 100 μΩcm. Moreover, the impurity concentration at the surface of the gate oxide film side of the single-crystal semiconductor film 29a is between 1×10¹⁹ and 1×10²¹/cm³, whereas the impurity concentration on the surface on the side at which the wirings are connected is between 1×10¹⁷ and 1×10¹⁹/cm³.

As will be described below, the semiconductor device according to Embodiment 1 is formed through transferring, onto an intermediate substrate, a portion of a semiconductor element that has been formed on a single-crystal semiconductor substrate, and then transferring it from the intermediate substrate to a glass substrate. Even if the metal wiring is connected from the face of the single-crystal semiconductor film on the side opposite from the gate insulating film side, it is still possible to reduce the resistance of the contact connection between the metal wiring and the single-crystal semiconductor film and to make a stabilized connection through the use of holes to the single-crystal semiconductor film.

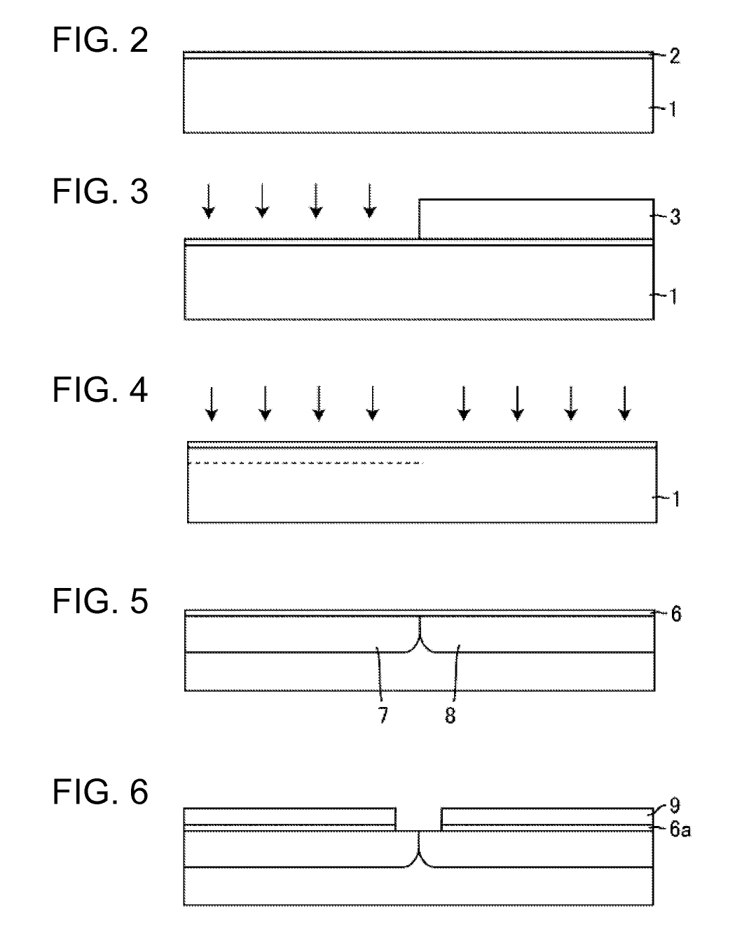

The method for manufacturing the semiconductor device according to the present invention will be explained using FIGS. 2 to 26. FIGS. 2 to 26 are flow charts illustrating the manufacturing process for the semiconductor device according to the present invention.

First, as illustrated in FIG. 2, a thermal oxide film 2 of about 30 nm is formed on a silicon substrate (a single-crystal silicon substrate) 1. The thermal oxide film 2 is for the purpose of preventing contamination of the surface of the silicon substrate during the ion implantation process, so it is not absolutely necessary. Following this, resist 3 that is formed on the thermal oxide film 2 is used as a mask, as illustrated in FIG. 3, and an N-type impurity element is implanted in the direction indicated by the arrows in FIG. 3, through ion implantation into an N-well forming region that is a region in which there is an opening in the resist. The use of phosphorus, for example, is preferred for the impurity element. Moreover, preferably the implantation energy is set to between about 50 and 150 KeV, and the dose is between about 1×10¹² and 1×10¹³ cm². At this time, preferably an implantation dose for an additional N-type impurity element is determined in consideration of the amount that will be canceled out by the P-type impurity if the P-type impurity is implanted into the entire surface of the silicon substrate 1 in a later process.

As illustrated in FIG. 4, after the resist 3 is removed, a P-type impurity element (such as boron) is implanted into the entire surface of the silicon substrate 1 in the direction illustrated by the arrows in FIG. 4. Preferably, boron, for example, is used as the impurity element. Furthermore, the implantation energy is set to between about 10 and 50 KeV and the dose is set to between about 1×10¹² and 1×10¹³ cm⁻². Note that because the coefficient of diffusion of phosphorus in silicon in a heat treatment is small when compared to that of boron, a heat treatment may be performed prior to the implantation of the boron element to diffuse the phosphorus appropriately into the silicon substrate in advance. Moreover, if one wishes to avoid the cancellation of the N-type impurity by the P-type impurity in the N-well region, the P-type impurity element may be implanted after forming resist over the N-well region. (In this case, there is no need to consider the cancellation by the P-type impurity when implanting the N-type impurity into the N-well region.)

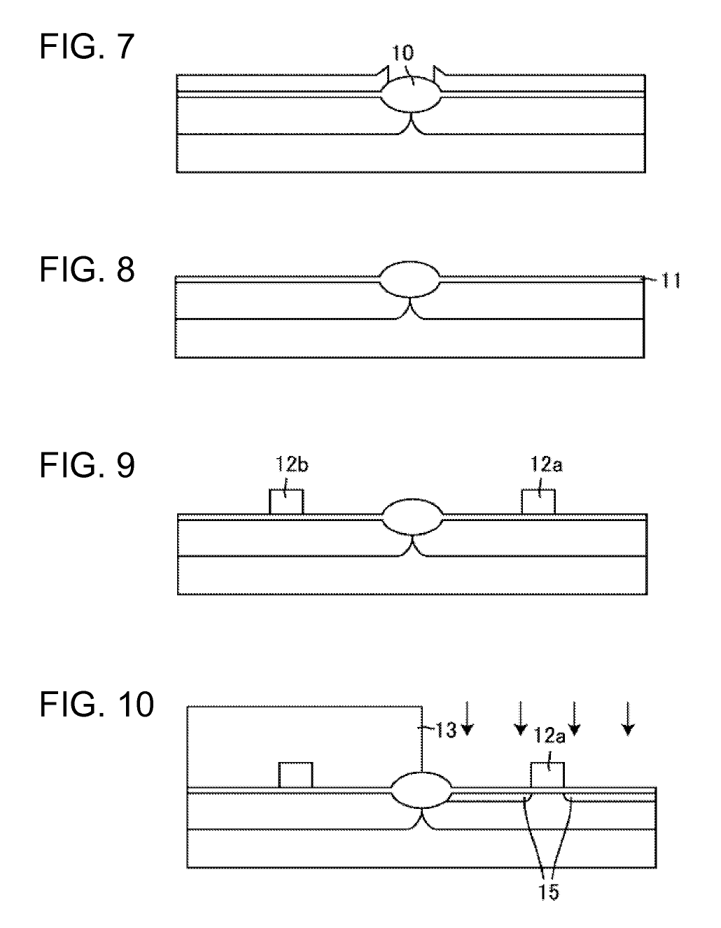

Following this, as illustrated in FIG. 5, a heat treatment is performed in an oxidizing ambient at between about 900 and 1,000° C. after removing the thermal oxide film 2. Doing so not only forms a thermal oxide film 6 to a thickness of about 30 nm, but also diffuses the impurity elements that have been implanted into the N-well region and the P-well region, to form the N-well region 7 and the P-well region 8. Further, a silicon nitride film 9 and the thermal oxide film 6a are formed, as illustrated in FIG. 6, by performing patterning after forming a silicon nitride film to a thickness of about 200 nm through a chemical vapor deposition (CVD) method. Next, LOCOS oxidation is performed using a heat treatment at between about 900 and 1,000° C. in an oxygen ambient to form a LOCOS oxide layer 10 with a thickness of between about 200 and 500 nm, as illustrated in FIG. 7. While the LOCOS oxide layer is for isolating the elements, a method other than LOCOS oxidation may be used. For example, the element isolation may be performed through shallow trench isolation (STI) or the like.

Next, a heat treatment is performed in an oxygen ambient at about 1000° C. after the removal of the silicon nitride film 9 and the thermal oxide film 6a. Doing so forms the gate oxide film 11 to a thickness of between about 10 and 20 nm, as illustrated in FIG. 8. Note that in order to control the threshold voltage of the transistors, after the silicon nitride film 9 is removed, an N-type or P-type impurity may be introduced, through ion implantation, into the region in which the NMOS or PMOS transistor is formed. Next, the gate electrode 12a of the NMOS transistor and the gate electrode 12b of the PMOS transistor are formed as illustrated in FIG. 9. The gate electrodes 12a and 12b may be formed through patterning after depositing polysilicon to a thickness of about 300 nm through a CVD method.

As illustrated in FIG. 10, a resist 13 is formed so as to expose the region in which the NMOS transistor will be formed, and ion implantation of an N-type impurity element, such as phosphorus, is performed in the direction indicated by the arrows in FIG. 10, using the gate electrode 12a as a mask, to form an N-type low-concentration impurity region 15, in order to form a lightly-doped drain (LDD) region. A phosphorus element, for example, may be used as the N-type impurity element. Preferable ion implantation conditions are, for example, a dose of between about 5×10¹² through 5×10¹³ cm⁻². Moreover, at this time a P-type impurity element, such as boron, or the like, may be implanted obliquely (HALO implantation) in order to suppress the short channel effect. The impurity concentration of the P-type impurity region formed within the channel region thereby is set to between 1×10¹⁷ and 5×10¹⁷/cm³.

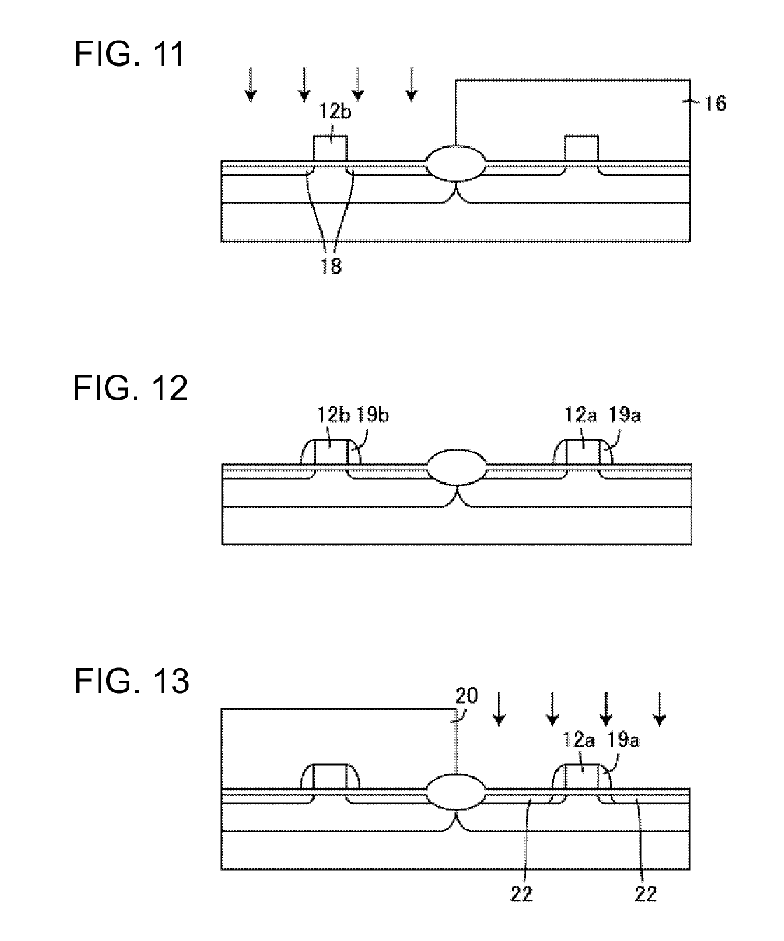

Next, a resist 16 is formed so as to expose the region in which the PMOS transistor will be formed, and, as illustrated in FIG. 11, ion implantation of a P-type impurity element, such as boron, is performed in the direction indicated by the arrows in FIG. 11, using the gate electrode 12b as a mask, to form a P-type low-concentration impurity region 18. A boron element, for example, may be used as the P-type impurity element. The ion implantation conditions are preferably a dose of between 5×10¹² and 5×10¹³ cm⁻², for example. Because the coefficient of thermal diffusion of boron is high, it may not be absolutely necessary to perform the P-type low-concentration impurity implantation if it is possible to form the PMOS low-concentration impurity region through mere thermal diffusion of the boron implanted by the P-type high-concentration impurity implantation into the PMOS transistor performed in a later step. Moreover, at this time an N-type impurity element, such as phosphorus, may be implanted obliquely (HALO implantation) in order to suppress the short channel effect. Doing so causes the impurity concentration of the N-type impurity region that is formed within the channel region to be between 1×10¹⁷ and 5×10¹⁷/cm³.

After removing the resist 16, anisotropic dry etching is performed after forming a silicon oxide (SiO₂) film through a CVD method or the like, to form SiO₂ side walls 19a and 19b on the walls on both sides of the gate electrodes 12a and 12b, as illustrated in FIG. 12. Then, as illustrated in FIG. 13, a resist 20 is formed so as to expose the region in which the NMOS transistor is formed, and ion implantation of an N-type impurity element, such as phosphorus or the like, is performed in the direction indicated by the arrows, using the gate electrode 12a and the side walls 19a as a mask, to form the N-type high-concentration impurity region 22. The impurity concentration in the N-type high-concentration impurity region 22 that is formed thereby is set to between 1×10¹⁹ and 1×10²¹/cm³.

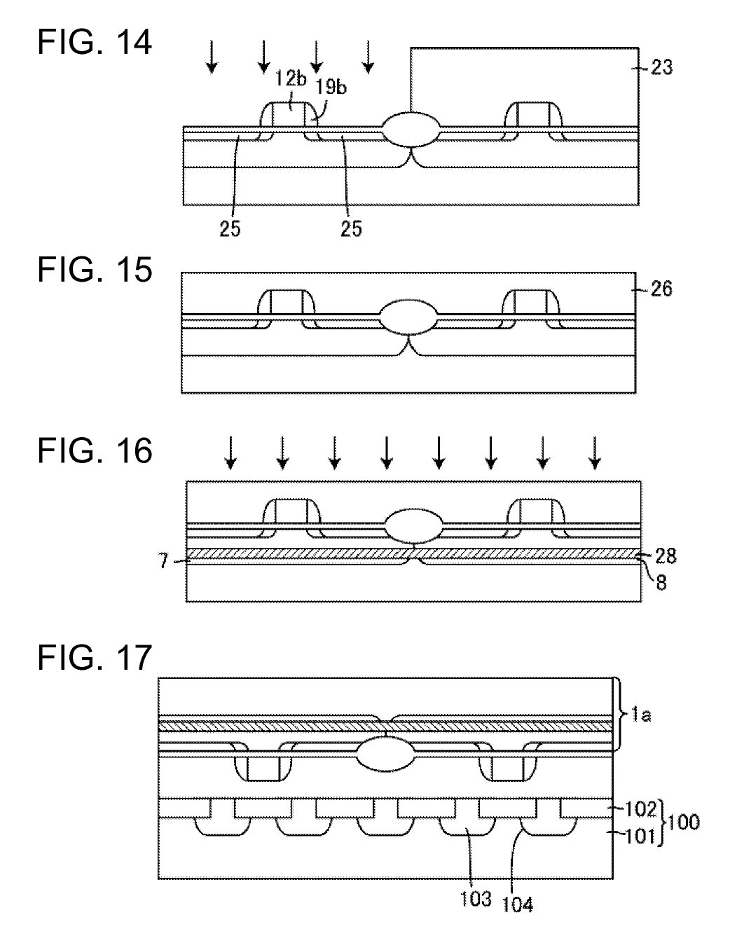

As illustrated in FIG. 14, a resist 23 is formed so as to expose the region in which the PMOS transistor will be formed, and implantation of a P-type impurity element, such as boron or the like, is performed in the direction indicated by the arrows, using the gate electrodes 12b and the side walls 19 as a mask to form a P-type high-concentration impurity region 25. The impurity concentration of the P-type high-concentration impurity region 25 that is formed thereby is set to between 1×10¹⁹ and 5×10²⁰/cm³. Thereafter, an activating heat treatment is performed to activate the impurity elements that have been implanted through ion implantation. The heat treatment is performed for 10 min. at 900° C., for example.

After the formation of an insulating film, such as SiO₂, CMP, or the like, is performed to form a planarizing film 26, as illustrated in FIG. 15. As illustrated in FIG. 16, a peeling layer 28 is formed through the use of ion implantation to implant, into the silicon substrate, a peeling substance that includes hydrogen and/or an inert element such as helium or neon. For the implantation conditions, in the case of hydrogen, for example, the dose is set to between 2 to ×10¹⁶ and 2×10¹⁷ cm⁻², and the implantation energy is set to between about 100 and 200 KeV.

The silicon substrate 1a wherein the peeling layer 28 or the like, have been formed is next bonded to an intermediate substrate 100 that has a separating structure. The intermediate substrate 100 will be explained below. FIG. 30 is a schematic plan view illustrating states during the manufacturing of the intermediate substrate. FIG. 30(a) is a schematic planar view, and FIG. 30(b) is a schematic cross-sectional diagram sectioned along the line X1-X2 in FIG. 30(a).

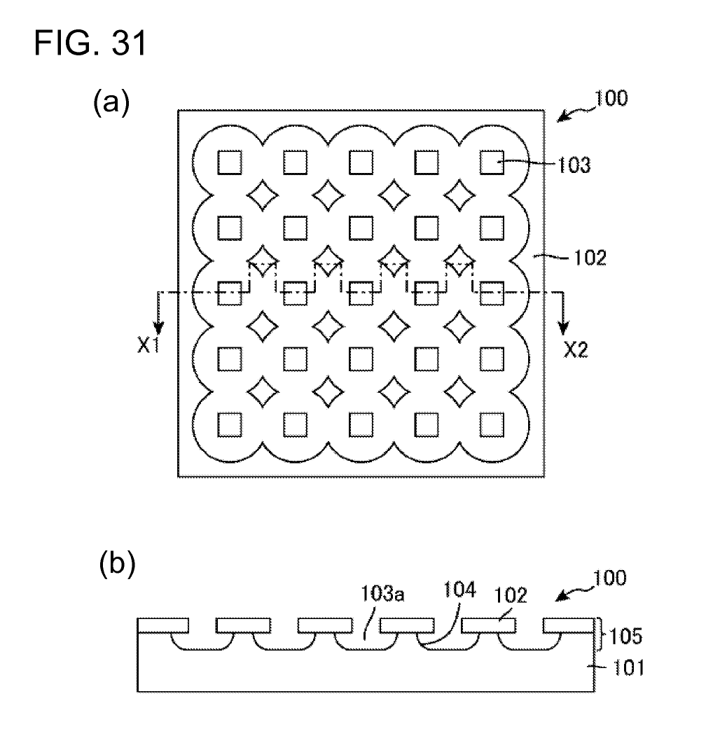

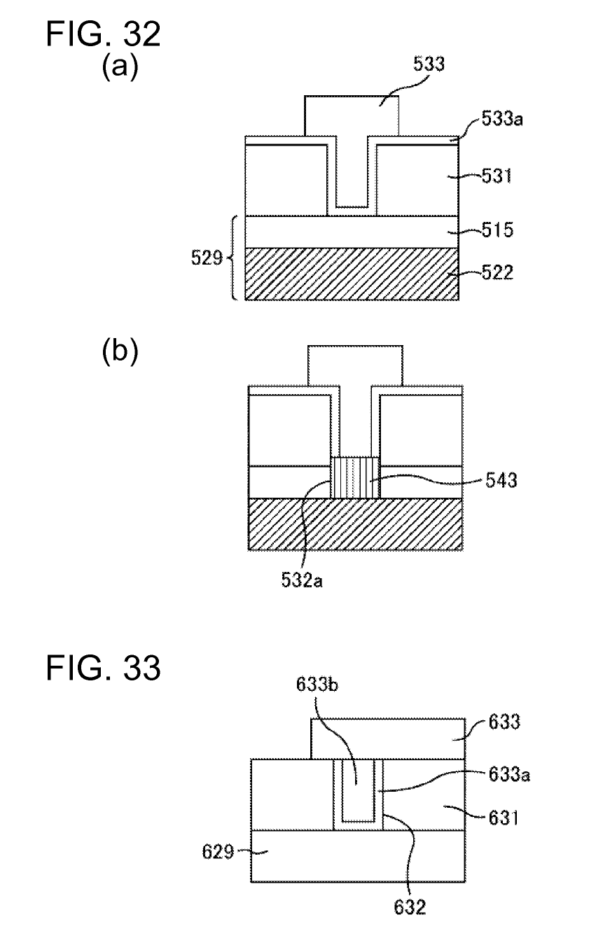

The intermediate substrate 100 can be manufactured using the process set forth below. First a thermal oxide film of between about 100 and 300 nm is formed on the top face of a silicon substrate through thermal oxidation. Thereafter patterning is performed using photolithography or the like to form openings 103, which are approximately 0.5 μm, with a pitch of about 1.5 μm, in the thermal oxide film to form the patterned thermal oxide film 102 as illustrated in FIGS. 30(a) and 30(b). Thereafter, the intermediate substrate 100 is manufactured, as illustrated in FIGS. 31(a) and 31(b), through etching using a gas that is able to etch silicon, such as XeF₂ or the like. Openings 103a are formed reaching to under the thermal oxide film 102 in the intermediate substrate 100, which has a separating structure 105 made from the thermal oxide film 102, columnar silicon structures, and the openings 103a. Note that the etching may instead be performed through wet etching using an alkali solvent, such as TMAH or the like. The diameters and heights of the columnar silicon structures 104 can be set as appropriate to produce an intermediate substrate 100 that can withstand a subsequent CMP process and that can be separated through a torsional stress.

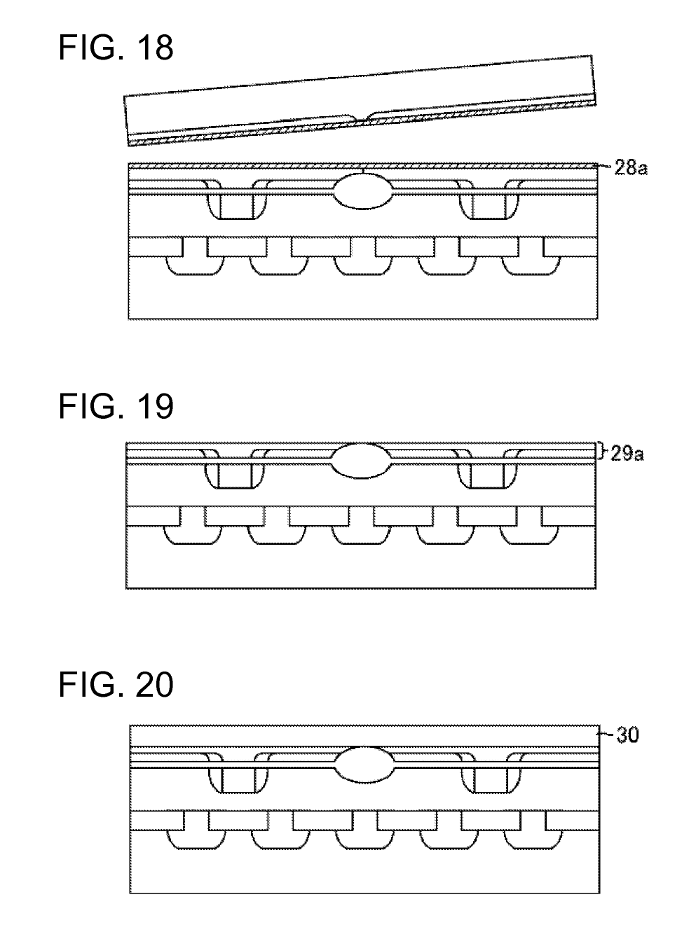

FIG. 17 illustrates the state in which the silicon substrate 1a in which the peeling layer 28 is formed is bonded to the intermediate substrate 100. At the time of bonding, bonding is performed through a hydrophilic treatment, through an SCl treatment, or the like, to the surface of the silicon substrate 1 in which the transistor has been formed, and to the surface of the intermediate substrate 100. After a heat treatment for about 2 hours at between 200 and 300° C. to increase the bonding strength, the temperature is increased to between about 550° C. and 600° C. to cause a portion of the silicon substrate 1 to separate along the peeling layer 28, so that the NMOS transistor and the PMOS transistor are transferred onto the intermediate substrate 100, as illustrated in FIG. 18. After the peeling layer 28a is removed through polishing, etching, or the like, the semiconductor portion that has been transferred onto the intermediate substrate 100 is polished or etched until the LOCOS oxide film 10 is exposed, as illustrated in FIG. 19, to form the single-crystal silicon film 29a and to perform the element isolation.

As illustrated in FIG. 20, after forming an SiO₂ film 30 to a thickness of about 100 nm to protect the surface of the single-crystal semiconductor (the surface of the single-crystal silicon film), a heat treatment is performed for between 30 min and two hours at between about 650° C. and 800° C. to remove the hydrogen that is in the single-crystal silicon film 29a, and also to completely eliminate the thermal donors and lattice vacancies, as well as to enable reactivation of the P-type impurities, to sufficiently recover the transistor characteristics and to enable stabilization of the characteristics. Note that preferably the temperature of the heat treatment is no more than 850° C. so as to be in a range that does not disrupt the impurity profiles in the transistors.

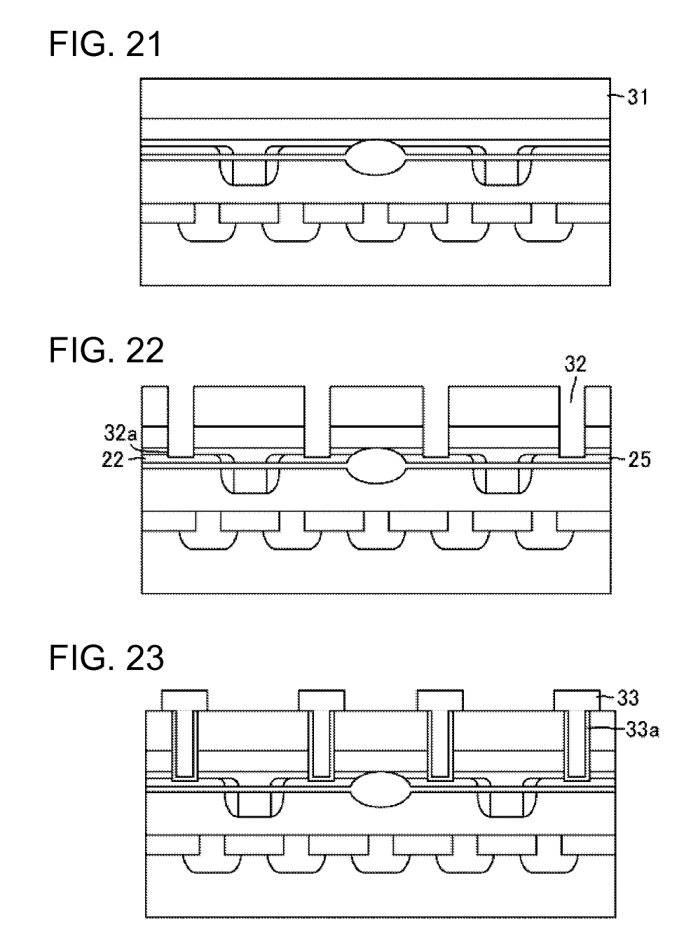

As illustrated in FIG. 21, an interlayer insulating film 31 is formed so as to adequately maintain the capacitance between the wirings without affecting the transistor characteristics. The contact holes 32 are formed as illustrated in FIG. 22. At this time, etching is performed more deeply beyond the surface of the single-crystal silicon film 29a so as to access the high-concentration impurity regions 22 that form the source and drain regions of the NMOS transistor and so as to access the high-concentration impurity regions 25 that form the source and drain regions of the PMOS transistor. That is, contact holes 32 are provided penetrating through the interlayer insulating film 31 and the SiO₂ layer 30, and, additionally, holes 32a are provided in the single-crystal silicon film 29a so as to access the high-concentration impurity regions. The impurity concentration of the high-concentration impurity regions in the regions accessed by the holes 32a is set to between 1×10¹⁹ and 1×10²¹/cm³. Doing this makes it possible to cause the contact resistance between the wiring and the single-crystal semiconductor film to be reliably low and stable. When actually forming the contact holes 32 and the holes 32a, preferably the single-crystal silicon film is etched taking into account the thickness of the silicon film up to the high-concentration impurity region, after exposing the surface of the silicon using an etching condition that has high selectivity between the oxide film and the silicon.

Next, a low-resistance metal material is deposited and patterned to form the metal wirings 33 as illustrated in FIG. 23. For the metal wiring 33, first, titanium (Ti) and titanium nitride (TiN) are deposited as a barrier layer 33a, after which an Al—Cu alloy is deposited as a low-resistance metal material. Here, a heat treatment has already been performed to both remove the hydrogen from within the single-crystal silicon film 29 and to eliminate the thermal donors and the lattice vacancies, and thus this makes it possible to prevent the diffusion of the metal materials, even when a metal material, such as Al—Si, Al—Cu, Cu, or the like, is used for the wiring.

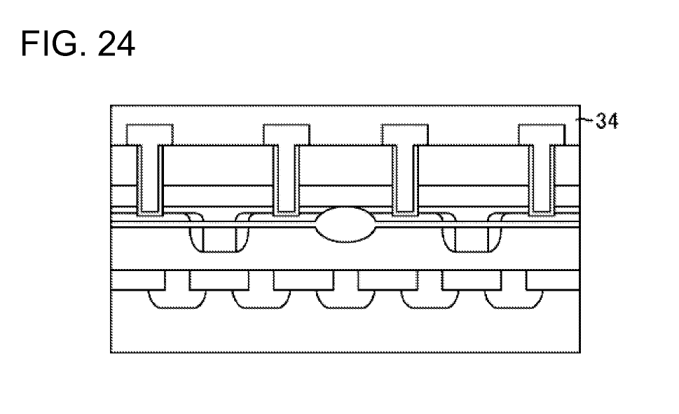

An SiO₂ film is deposited using PECVD or the like, using a mixed gas of TEOS (tetraethoxysilane) and oxygen so as to cover the metal wirings 32, and planarization is performed using CMP to form a planarizing film 34, as illustrated in FIG. 24.

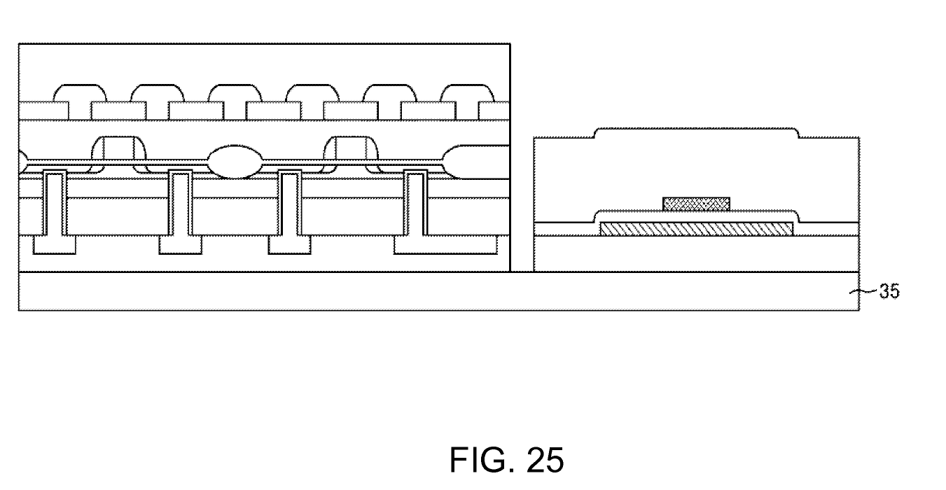

The intermediate substrate 100 is separated into a prescribed size, and a hydrophilic treatment is performed through soaking on the planarizing film 34 that is disposed on the divided intermediate substrate 100a and on the bonding surface of an insulating substrate 35, which has an insulating surface, in a solution that includes hydrogen peroxide, such as SCl, or the like. Then, alignment and bonding are performed to produce the state illustrated in FIG. 25. At this time, a non-single-crystal thin-film transistor, including a non-single-crystal silicon film 37, a gate insulating film 38, and a gate electrode 39, has already been formed on the glass substrate 35. Moreover, insulating films 36 and 40 are provided as layers above and below the non-single-crystal thin-film transistor.

In order to perform excellent bonding, preferably a condition in which the average surface roughness Ra is no more than about 0.2 to 0.3 nm is fulfilled. The average surface roughness Ra can be measured using atomic force microscopy (AFM). Furthermore, while the planarizing film 34 that is disposed on the intermediate substrate and the glass substrate 35 are bonded through van der Waals force and hydrogen bonding, thereafter a heat treatment is performed at between 400 and 600° C. to convert into strong bonds between the atoms through the following reaction:

—Si—OH (surface of the glass substrate)+—Si—OH (surface of the planarizing film 34)→Si—O—Si+H₂O

If the metal wiring 33 is one that uses a low-resistance metal material such as aluminum, tungsten, molybdenum, or the like, then preferably the heat treatment is performed at a lower temperature.

Note that instead of the glass substrate 35, a metal substrate, such as stainless steel, with a surface that is covered with an insulating material (such as SiO₂, SiN, or the like) may be used. This type of substrate has superior durability to physical shock, and is suitable when there is no need for the substrate to be transparent, such as in an organic EL display. Moreover, it may instead be a plastic substrate wherein the surface is covered with SiO₂. This form is well-suited to a lighter display. In this case, the intermediate substrate and the plastic substrate may be bonded together using an adhesive material or the like.

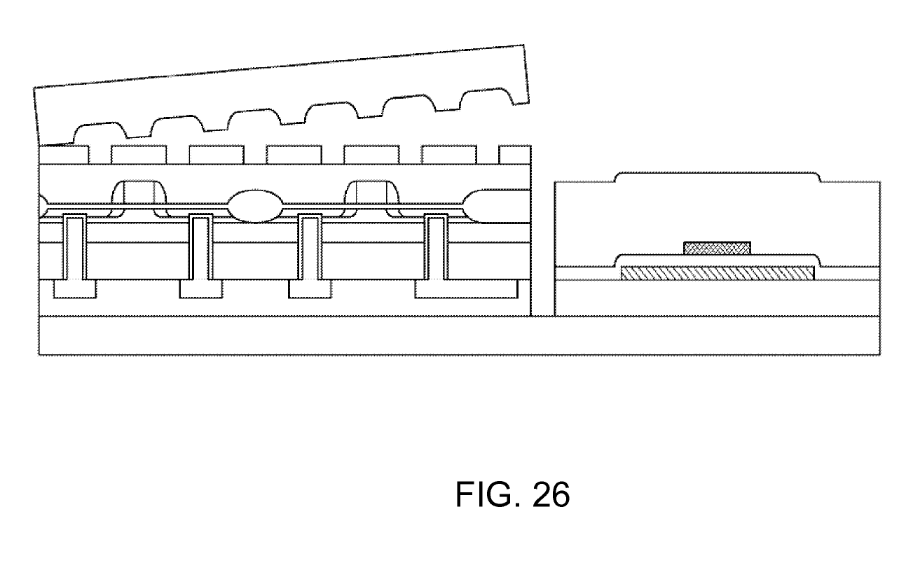

After an adequate bonding strength has been secured, it is possible to separate the intermediate substrate at the separating structure part, as illustrated in FIG. 26, through applying a force such as twisting, sliding to the side, or pulling and peeling to the intermediate substrate 100a. After etching away the residual columnar silicon portions and thermal oxide film 102 on the glass substrate, an interlayer insulating film 42 is formed to a thickness of about 500 nm through CVD, or the like, using TEOS and oxygen. Thereafter, contact holes are opened and a metal wiring layer of aluminum or the like, is deposited and patterned to form metal wirings 42. The semiconductor device illustrated in FIG. 1 is formed thereby.

As described above, the metal wirings can be formed after forming contact holes so as to access the high-concentration impurity regions that form the source and drain regions of the transistor, after subjecting the single-crystal silicon film to a heat treatment at a high temperature on the intermediate substrate in order to restore defects and reduce thermal donors within the crystal and in order to activate the inactivated boron. Doing so makes it possible to form, on a glass substrate, a single-crystal silicon film transistor having extremely low values in parasitic resistance, such as resistance in the wirings and contact resistance, with a sharp slope (between 65 and 80 mV/dec) for the threshold characteristics. Moreover, this makes it possible to improve the drop in voltage that is caused by the parasitic resistance and the like, improving the transistor characteristics, and also to drive the transistor at higher speeds through reducing the operating delays due to the resistances. Furthermore, the ability to obtain stable contact resistances can contribute to improvements in reproducibility and yields at the time of manufacturing.

### Embodiment 2

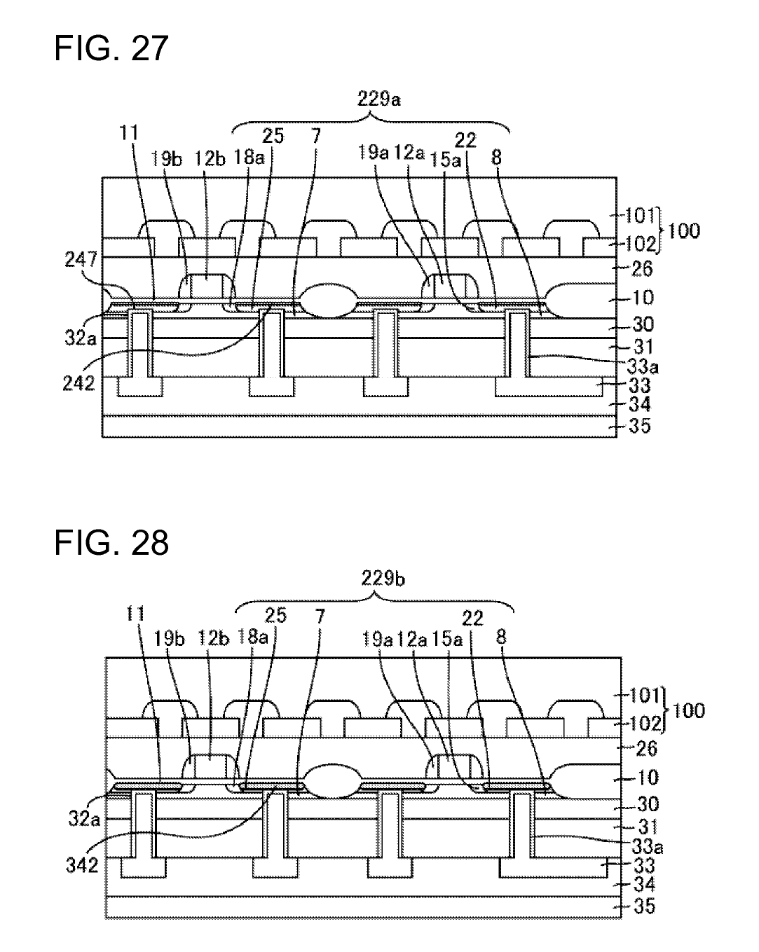

FIG. 27 is a schematic cross-sectional diagram illustrating the structure of a semiconductor device according to Embodiment 2. Aside from the provision of a metal silicide layer on the gate insulating film side surface of the high-concentration impurity region, it is essentially identical to the semiconductor device according to Embodiment 1. As illustrated in FIG. 27, a metal silicide layer is formed on the surfaces of the high-concentration impurity regions 22 and 25 of the transistor on the gate electrode side. In this type of structure, the high-concentration impurity region 22 or 25 is connected from the metal wiring 33 to the low-resistance metal silicide layer 242 through only an extremely short distance in the direction of layer thickness, to form an electric current path to the channel region of the NMOS or PMOS transistor, making it possible to reduce the parasitic resistance more effectively. Note that the resistivity of the single-crystal silicon film 229a at the contact face 247 between the metal wiring 33 and the single-crystal silicon film 229a is set to between 0.01 Ωcm and 100 μΩcm. Moreover, the impurity concentration on the surface on the gate oxide film 11 side of the single-crystal semiconductor film 229a is between 1×10¹⁹ and 1×10²¹/cm³, and the impurity concentration at the surface on the side to which the wiring is connected is between 1×10¹⁷ and 1×10¹⁹/cm³.

The method for forming the metal silicide layer 242 in the high-concentration impurity region will be described below.

After source and drain ion implantation and after the activating heat treatment, the oxide film is removed through wet etching, or the like, to expose the source and drain semiconductor silicon surfaces and the gate electrode surfaces. Thereafter, a metal for the silicide is deposited through sputtering or the like (for example, titanium at approximately 50 nm). Following this, a short heat treatment is performed at between about 600 and 700° C., to cause a silicide reaction with the metal in the parts in which the silicon of the source, drain, and gate electrodes is exposed, to form a silicide, and unreacted metal is removed through sulfuric acid and aqueous hydrogen peroxide, aqueous ammonia hydrogen peroxide, or the like. The metal silicide layer is formed thereby. When forming the silicide layer, silicide may be formed on the top portion of the gate electrode (the side that is opposite from the gate insulating film) as well. Metal silicides includes, for example, TiSi₂ (between 13 and 16 μΩcm), CoSi₂ (20 μΩcm), and TaSi₂ (between 35 and 45 μΩcm).

### Embodiment 3

FIG. 28 is a schematic cross-sectional diagram illustrating the structure of a semiconductor device according to Embodiment 3. The semiconductor device according to Embodiment 3 is identical to that of Embodiment 2 aside from the metal silicide on the surface of the high-concentration impurity region on the gate insulating film side being thicker than that in Embodiment 2 and the wiring contacting the metal silicide layer directly through the formation of holes that are provided in the single-crystal silicon layer so as to access the metal silicide layer. Note that the resistivity of the single-crystal silicon film 229b at the contact face 247 between the metal wiring 33 and the single-crystal semiconductor film 229b (the resistivity at the surface of the metal silicide layer 342 that contacts the wiring 33) is set to be between 0.01 Ωcm and 1 μΩcm. Moreover, the impurity concentration at the surface of the single-crystal semiconductor film 229b on the gate oxide film 11 side is between 1×10¹⁹ and 1×10²¹/cm³, and the impurity concentration on the surface on the side whereon the wiring is connected is between 1×10¹⁷ and 1×10¹⁹/cm³.

As illustrated in FIG. 28, a metal silicide layer 342 is formed on the surface of the high-concentration impurity region 22 or 25 of the MOS transistor on the gate electrode side, and the metal wiring 33 may contact the low-resistance metal silicide layer 342 directly. Such a structure makes it possible to reduce even further the parasitic resistance of the electric current path to the channel region of the NMOS or PMOS transistor.

### Embodiment 4

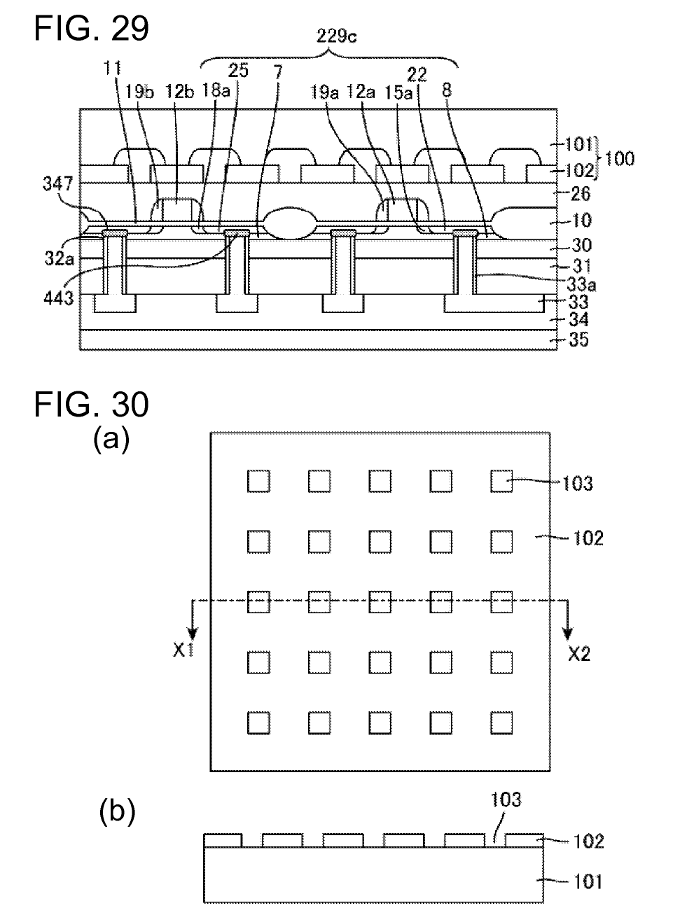

FIG. 29 is a schematic cross-sectional diagram illustrating the state wherein the intermediate substrate is bonded in the manufacturing process for a semiconductor device according to Embodiment 4. As illustrated in FIG. 29, a metal silicide portion 443 may be formed in a part at the bottom of a contact hole, where the high-concentration impurity region 22 or 25 contacts the metal silicide portion 443. In this case, a metal such as titanium, nickel, or cobalt may be used in forming the metal silicide. These metals undergo a silicide reaction while consuming silicon when forming a silicide through a heat treatment at between about 400 and 600° C. after being deposited into the contact hole that is formed in the SiO₂ film 30 and the interlayer insulating film 31 and in a recessed portion that is provided in the single-crystal semiconductor film 29a. The amount of silicon consumed is determined by the respective ratios for the titanium, nickel, and cobalt materials, and determined by the thickness of the film deposited for any of the materials. Because of this, it is possible to control, through setting the optimal deposited film thickness, the thickness of the metal silicide portion 443 that is formed. Consequently, it is possible to perform control so that, even if the high-concentration impurity region is not accessed at the time that the contact is formed, the metal silicide portion 443 will access the high-concentration impurity region through the formation of the metal silicide portion 443 thereafter. The benefit of this structure is that it is not necessary to remove the single-crystal semiconductor film so as to reach the high-concentration impurity region. Because of this, as long as a contact is formed so as to expose the surface of the silicon, the metal silicide can be connected to the high-concentration impurity region with excellent repeatability and stability, through setting appropriately the deposited film thickness for the titanium, nickel, or cobalt that forms the metal silicide portion 443. Note that the resistivity of the single-crystal silicon film 229c at the contact face 347 between the metal wiring 33 and the single-crystal semiconductor film 229c is set to be between 0.01 Ωcm and 100 μΩcm. Moreover, the impurity concentration at the surface of the single-crystal semiconductor film 229c on the gate oxide film 11 side is between 1×10¹⁹ and 1×10²¹/cm³, and the impurity concentration on the surface on the side whereon the wiring is connected is between 1×10¹⁷ and 1×10¹⁹/cm³.

Note that Embodiment 4 is able to provide a structure that further improves the resistance value through combining Embodiment 2 and Embodiment 3, and that it also has high stability and excellent manufacturing control. Moreover, a W (tungsten) plug contact may be used for the contact. Doing so makes it possible to reduce the contact resistance, and makes it possible to make a stable connection even in an extremely small contact hole.

When forming the tungsten contact plug, a barrier metal (such as, for example, about 20 nm of titanium followed by about 100 nm of titanium nitride) is deposited using CVD, sputtering, or the like, after forming a contact hole through dry etching or the like in the interlayer insulating film. Then, tungsten is deposited through CVD or the like to fill the contact hole. Then, the tungsten on the surface is removed through CMP or etch-back, or the like, and similarly, the barrier metal on the surface is removed through CMP or etch-back, or the like. The tungsten plug contact is formed in this way. The formation of the tungsten plug contact can be applied also to the cases in Embodiments 1 through 3 set forth above.

Note that the present application is based on Japanese Patent Application 2009-018674, for which application was made on Jan. 29, 2009, and claims priority based on the Paris Convention and on the laws of the countries to which it extends. The content of that application, in its entirety, is incorporated by reference into the present application.

### DESCRIPTION OF REFERENCE CHARACTERS

1, 1a, 1b: silicon substrates (single silicon substrates)
2, 6, 6a, 102: thermal oxide films
3, 13, 16, 20, 23: resist
7: N-well region
8: P-well region
9: silicon nitride film
10: LOCOS oxide film
11, 38: gate oxide film
12a, 12a, 39: gate electrodes
15, 15a: N-type low-concentration impurity regions
18, 18a: P-type low-concentration impurity regions
19: side wall
22: N-type high-concentration impurity region
25: P-type high-concentration impurity region
26, 34: planarizing films
28, 28a: peeling layers
29a, 229a, 229b, 229c: single-crystal silicon films (single-crystal semiconductor films)
30: SiO₂ film
31, 42, 531: interlayer insulating films
32, 632: contact holes
32a, 532a: holes
33, 42, 533, 633: metal wirings
33a, 533a, 633a: barrier metal layers
35: insulating substrate
36, 40: insulating films
37: non-single-crystal silicon film
45a, 45b: channel regions
46a, 46b: source/drain regions
47, 247, 347: faces (contact faces)
50: semiconductor device
100: intermediate substrate
103: opening
104: columnar Si structure
242, 342, 543: metal silicide layers
443: metal silicide portion
515: low-concentration impurity region
522: high-concentration impurity region
529, 629: single-crystal semiconductor films
633b: tungsten

1. A semiconductor device comprising, on a substrate, a semiconductor element having a single-crystal semiconductor film and a wiring connected to the single-crystal semiconductor film,
wherein in the single-crystal semiconductor film, an impurity concentration on one surface side is different from an impurity concentration on another surface side, the wiring being connected to the surface side on which the impurity concentration is lower, the resistivity of a region of the single-crystal semiconductor film to which the wiring is connected being no less than 1 μΩcm and no more than 0.01 Ωcm.

2. The semiconductor device according to claim 1, wherein the single-crystal semiconductor film is provided with a hole on the surface side on which the impurity concentration is lower, and the wiring is connected to the single-crystal semiconductor film through said hole.

3. The semiconductor device according to claim 2, wherein the hole is formed through removal of a portion of the single-crystal semiconductor film on the surface side on which the impurity concentration is lower.

4. The semiconductor device according to claim 1, wherein the semiconductor element is a transistor having a single-crystal semiconductor film, a gate insulating film, and a gate electrode layered in that order,
wherein the single-crystal semiconductor film has the gate insulating film on the surface side on which the impurity concentration is higher, and
wherein wirings are connected to a source region and a drain region of the transistor.

5. The semiconductor device according to claim 4, wherein the transistor has a side wall on a side face of the gate electrode;
wherein the single-crystal semiconductor film has a low-concentration impurity region and a high-concentration impurity region having an impurity concentration higher than that of the low-concentration impurity region,
wherein said gate electrode is self-aligning with a channel region of a semiconductor layer,
wherein said side wall is self-aligning with the low-concentration impurity region, and
wherein said low-concentration impurity region is formed between the high-concentration impurity region and the channel region.

6. The semiconductor device according to claim 5, wherein in the transistor, the high-concentration impurity region and the wiring are connected.

7. The semiconductor device according to claim 4, wherein the single-crystal semiconductor film has a metal silicide layer on a surface of at least one of the source region and thea drain region on a side of the gate insulating film.

8. The semiconductor device according to claim 1, wherein the single-crystal semiconductor film has an impurity concentration gradient from the surface side on which the impurity concentration is lower to the surface side on which the impurity concentration is higher, and
wherein a hole extends to a region of the single-crystal semiconductor film in which the impurity concentration is no less than 1×10¹⁹/cm³ and no more than 1×10²¹/cm³.

9. The semiconductor device according to claim 2, wherein the single-crystal semiconductor film has a metal silicide portion in the hole.

10. The semiconductor device according to claim 9, wherein the metal silicide portion includes at least one element selected from a group comprising titanium, nickel, and cobalt.

11. The semiconductor device according to claim 1, wherein the wiring includes at least one element selected from a group comprising aluminum, molybdenum, tungsten, and copper.

12. The semiconductor device according to claim 1, wherein the wiring has a barrier metal layer that includes at least one element selected from a group comprising titanium, titanium nitride and tantalum nitride.

13. The semiconductor device according to claim 12, further comprising an interlayer insulating film on a side of the single-crystal semiconductor film on which the impurity concentration is lower,
wherein a contact hole is formed in said interlayer insulating film, and
wherein the wiring has a plug contact portion in which tungsten is filled into the contact hole.

14. The semiconductor device according to claim 1, wherein the single-crystal semiconductor film includes at least one element selected from a group comprising a group IV semiconductor, a group II-VI compound semiconductor, a group III-V compound semiconductor, a group Iv-Iv compound semiconductor, and a mixed crystal including same group elements.

15. The semiconductor device according to claim 14, wherein the single-crystal semiconductor film includes a group IV semiconductor, and
wherein said group IV semiconductor is silicon.

16. The semiconductor device according to claim 1, wherein the substrate is a glass substrate.

17. The semiconductor device according to claim 1, wherein the substrate is a resin substrate.

18. The semiconductor device according to claim 1, wherein the semiconductor device includes an NMOS transistor and a PMOS transistor.

19. The semiconductor device according to claim 1, wherein the single-crystal semiconductor film is that which is peeled through a peeling layer including a peeling substance formed in a single-crystal semiconductor substrate.

20. The semiconductor device according to claim 19, wherein the peeling substance includes at least one of hydrogen and an inert gas element.

21. A semiconductor device having, on a substrate, a semiconductor element having a single-crystal semiconductor film and a wiring connected to the single-crystal semiconductor film,
wherein the semiconductor device is a transistor having a single-crystal semiconductor film, a gate insulating film, and a gate electrode layered in that order,
wherein the single-crystal semiconductor film has an impurity concentration on one surface side that is different from an impurity concentration on another surface side, and has a gate insulating film on the surface side on which the impurity concentration is higher,
wherein said wiring is connected to a source region and a drain region of the transistor from the surface side on which the impurity concentration is lower,
wherein said single-crystal semiconductor film has a metal silicide layer on a surface of at least one of the source region and the drain region on a side of the gate insulating film, and
wherein the metal silicide layer is connected to the wiring, and the resistivity of a region to which the wiring is connected is no less than 1 μΩcm and no more than 0.01 Ωcm.

22. A method for manufacturing the semiconductor device of claim 1, comprising:
transferring onto an intermediate substrate a semiconductor element or a portion thereof, formed in a single-crystal semiconductor substrate; and
transferring said semiconductor element or the portion thereof from the intermediate substrate onto a substrate.

23. The method for manufacturing the semiconductor device according to claim 22, further comprising performing a heat treatment on the semiconductor element that is disposed on an intermediate substrate.

24. The method for manufacturing the semiconductor device according to claim 23, further comprising forming the wiring after performing the heat treatment on the semiconductor element that is disposed on the intermediate substrate.
